(19) United States
(12) Patent Application Publication
(10) Pub. No.: US 2024/0327702 A1
(43) Pub. Date: Oct. 3, 2024

(54) CURABLE COMPOSITION, CURED LAYER USING THE COMPOSITION AND DISPLAY DEVICE INCLUDING THE CURED LAYER

(71) Applicant: SAMSUNG SDI CO., LTD., Yongin-si (KR)

(72) Inventors: Yonghee KANG, Suwon-si (KR); Bumjin LEE, Suwon-si (KR); Hyunjoo HAN, Suwon-si (KR); Kyunghee KANG, Suwon-si (KR); Jihyeon YIM, Suwon-si (KR)

(21) Appl. No.: 18/605,566

(22) Filed: Mar. 14, 2024

(30) Foreign Application Priority Data
Mar. 29, 2023 (KR) 10-2023-0041365

(51) Int. Cl. C09K 11/06; C08K 9/04; C09D 11/107; C09D 11/32

(52) U.S. Cl. CPC C09K 11/06; C09D 11/107; C09D 11/32; C08K 9/04; C08K 2201/011

(57) ABSTRACT

A curable composition including surface-modified quantum dots and a polymerizable compound is provided. A cured layer produced using the curable composition, and display device including the cured layer are also provided.

### CROSS-REFERENCE TO RELATED APPLICATION

This application claims priority to and the benefit of Korean Patent Application No. 10-2023-0041365 filed on Mar. 29, 2023, in the Korean Intellectual Property Office the entire content of which is incorporated herein by reference.

### BACKGROUND

### 1. Field

This disclosure relates to a curable composition, a cured layer utilizing the composition, and a display device including the cured layer.

### 2. Description of the Related Art

In general, quantum dots may include surface characteristics (e.g., hydrophobicity), which limit or prevent dispersion of the quantum dots throughout a solvent. Accordingly, it is difficult to introduce quantum dots into a polar system including other components such as a binder or a curable monomer.

For example, even in the case of a quantum dot ink composition being actively researched, a polarity of the composition is relatively low in an initial step (process) and it may be dispersed in a solvent utilized in a curable composition having a high hydrophobicity. Because it is difficult to achieve a content of 20 wt %, or more, of the quantum dots based on a total amount of the composition, it may be impossible to increase light efficiency of the ink over a certain level. Even though the quantum dots are additionally added and dispersed in order to increase light efficiency, the resultant viscosity may then exceed a range (e.g., about 12 centipoise (cPs)) capable of, or suitable for, ink-jetting and thus proper processability may not be satisfied or achieved.

1 In order to achieve a viscosity range capable of, or suitable for, ink-jetting, an ink solid content (e.g., amount) may be lowered by dissolving (e.g., including) a solvent in quantities of 50 wt %, (or more) based on a total amount of the composition. The additional solvent may also provide a somewhat satisfactory result in terms of viscosity, but nozzle drying due to solvent volatilization, nozzle clogging, and/or a thickness reduction of single film (e.g., over time after ink-jetting) may become worse. Therefore, in applications to actual processes, it is difficult to control a thickness deviation after curing, and it is difficult to control the viscosity range of the quantum dot ink composition by adding additional solvent.

Accordingly, a solvent-free quantum dot ink composition that does not include a solvent may be the most desirable form to be applied to an actual process. The current technique of applying a quantum dot itself to a solvent type or kind of composition is now limited to a certain extent.

A solvent-free curable composition (i.e., quantum dot ink composition) includes an excessive amount of a polymerizable compound that may cause nozzle clogging and discharge failures according to nozzle drying due to volatility. The polymerizable compound may also cause a thickness reduction of a single film due to volatilization following the ink composition being ink-jetted in a pattern partition wall pixel. Successful implementation of a solvent-free curable composition (i.e., quantum dot ink composition) also requires (or there is a desire for) a method to enhance or improve the optical characteristics of the solvent-free curable composition.

### SUMMARY

One or more aspects of embodiments of the present disclosure are directed toward a curable composition having excellent or suitable light resistance.

One or more aspects of embodiments of the present disclosure are directed toward a cured layer produced utilizing the curable composition.

One or more aspects of embodiments of the present disclosure are directed toward a display device including the cured layer.

One or more embodiments provide a curable composition including (A) quantum dots including at least one functional group selected from among functional groups represented by Chemical Formulas 1, 2-1, 2-2, and 2-3; and (B) a polymerizable compound.

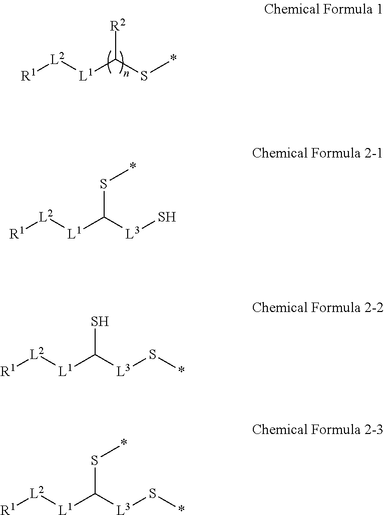

In Chemical Formulas 1, 2-1, 2-2, and 2-3,
L¹ may be a single bond, a substituted or unsubstituted C1 to C20 alkylene group, an ether group (*—O—*), *—(X-L^{a})-* (wherein X may be an oxygen atom or a sulfur atom, and L^{a} may be a substituted or unsubstituted C1 to C10 alkylene group) or a combination thereof,
L² and L³ may each independently be a single bond or a substituted or unsubstituted C1 to C20 alkylene group,
R¹ may be a substituted or unsubstituted heterocyclic group,
R² may be a hydrogen atom or a substituted or unsubstituted C1 to C20 alkyl group, n may be an integer of 0 or 1, and
“*” may be a linking point with a different atom, a same chemical formula, or a different chemical formula.

The heterocyclic group may include a nitrogen atom, an oxygen atom, a sulfur atom, or a combination thereof.

The heterocyclic group may be represented by any one of Chemical Formulas H-1 to H-12.

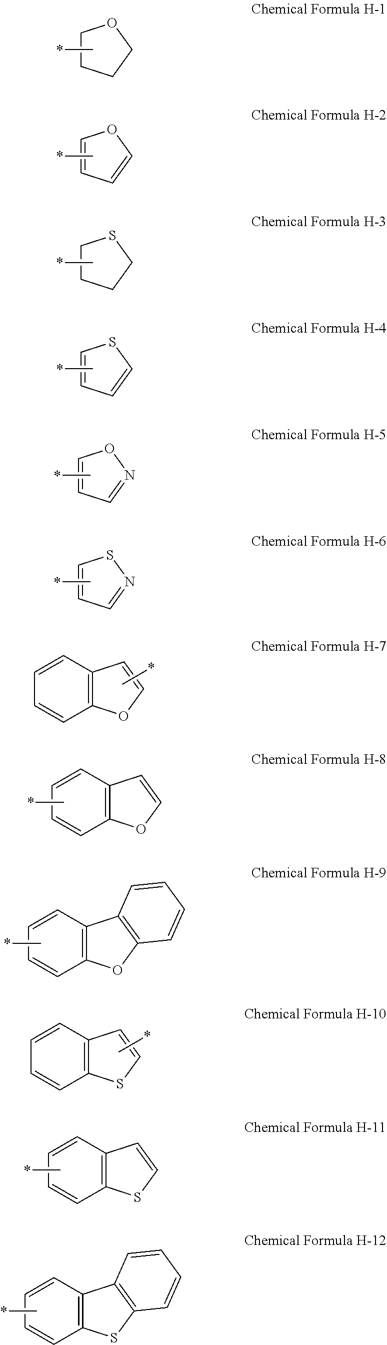

The functional group represented by Chemical Formula 1 may be represented by any one of Chemical Formulas 1A to 1C.

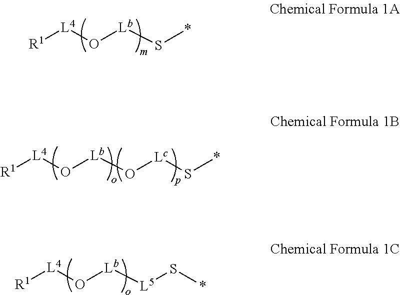

In Chemical Formulas 1A to 1C,
L⁴ may be a single bond or a substituted or unsubstituted C1 to C20 alkylene group,
L⁵, L^{b}, and L^{c} may each independently be a substituted or unsubstituted C1 to C20 alkylene group,
R¹ may be a substituted or unsubstituted heterocyclic group, and
m, o, and p may each independently be an integer of 1 to 100.

The functional groups represented by Chemical Formulas 2-1 to 2-3 may be each represented by any one of Chemical Formulas 2A to 2F.

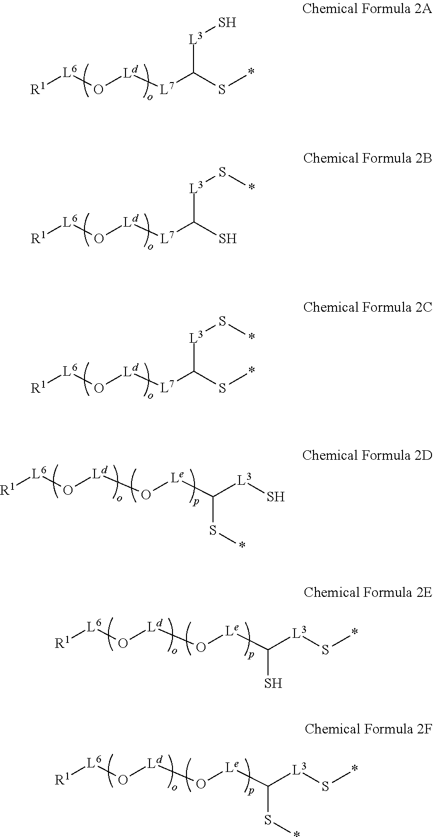

In Chemical Formulas 2A to 2F,
L³, L⁷, and L⁶ may each independently be a single bond or a substituted or unsubstituted C1 to C20 alkylene group,
L^{d} and L^{e} may each independently be a substituted or unsubstituted C1 to C20 alkylene group,
R¹ may be a substituted or unsubstituted heterocyclic group, and
o and p may each independently be an integer of 1 to 100.

The functional group may be represented by any one of Chemical Formulas 10 to 18.

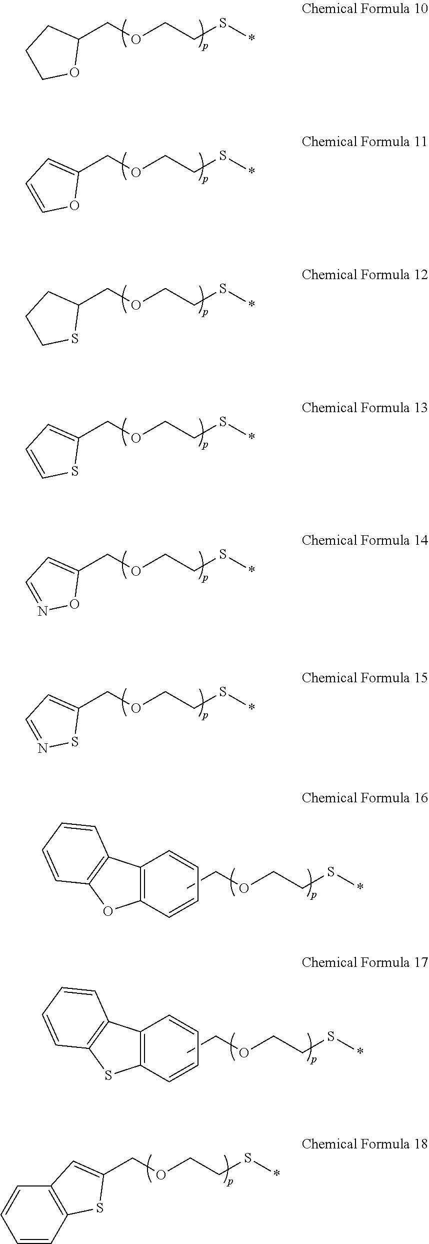

In Chemical Formulas 10 to 18,
p may be an integer from 1 to 100.

The functional group may be represented by any one of Chemical Formulas 20 to 22.

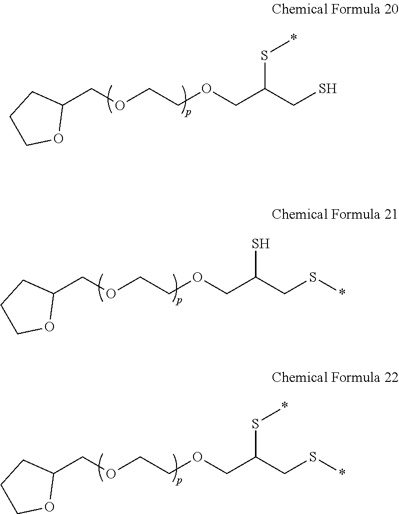

### In Chemical Formulas 20 to 22,

p may be an integer from 1 to 100.

Some embodiments provide a curable composition including (A) surface-modified quantum dots with a surface-modifying material (e.g., dots including the surface-modifying material or modified by the surface-modifying material); and (B) polymerizable compound, wherein the surface-modifying material includes at least one selected from among compounds represented by Chemical Formulas 3 and 4.

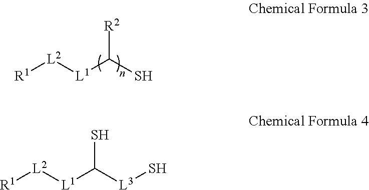

In Chemical Formulas 3 and 4,
L¹ may be a single bond, a substituted or unsubstituted C1 to C20 alkylene group, an ether group (*—O—*), *—(X-L^{a})-* (wherein X may be an oxygen atom or a sulfur atom, and L^{a} may be a substituted or unsubstituted C1 to C10 alkylene group) or a combination thereof,
L² and L³ may each independently be a single bond or a substituted or unsubstituted C1 to C20 alkylene group,
R¹ may be a substituted or unsubstituted heterocyclic group,
R² may be a hydrogen atom or a substituted or unsubstituted C1 to C20 alkyl group,
n may be an integer of 0 or 1, and
“*” may be a linking point with a different atom, a same chemical formula, or a different chemical formula.

The heterocyclic group may be as described herein.

The compound represented by Chemical Formula 3 may be represented by any one of Chemical Formulas 3A to 3C.

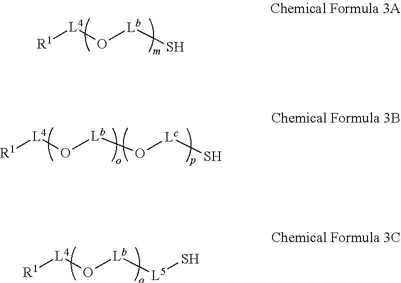

In Chemical Formulas 3A to 3C,
L⁴ may be a single bond or a substituted or unsubstituted C1 to C20 alkylene group,
L⁵, L^{b}, and L^{c} may each independently be a substituted or unsubstituted C1 to C20 alkylene group,
R¹ may be a substituted or unsubstituted heterocyclic group, and
m, o, and p may each independently be an integer of 1 to 100.

The functional group represented by Chemical Formula 4 may be each represented by any one of Chemical Formulas 4A and 4B.

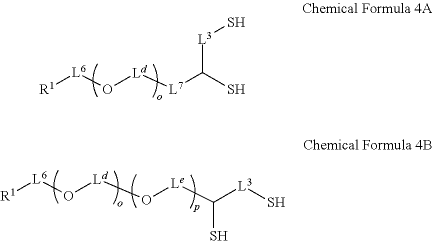

In Chemical Formulas 4A to 4B
L³, L⁷, and L⁶ may each independently be a single bond or a substituted or unsubstituted C1 to C20 alkylene group,
L^{d} and L^{e} may each independently be a substituted or unsubstituted C1 to C20 alkylene group,
R¹ may be a substituted or unsubstituted heterocyclic group, and
o and p may each independently be an integer of 1 to 100.

The surface-modifying material may be represented by any one of Chemical Formulas 30 to 38.

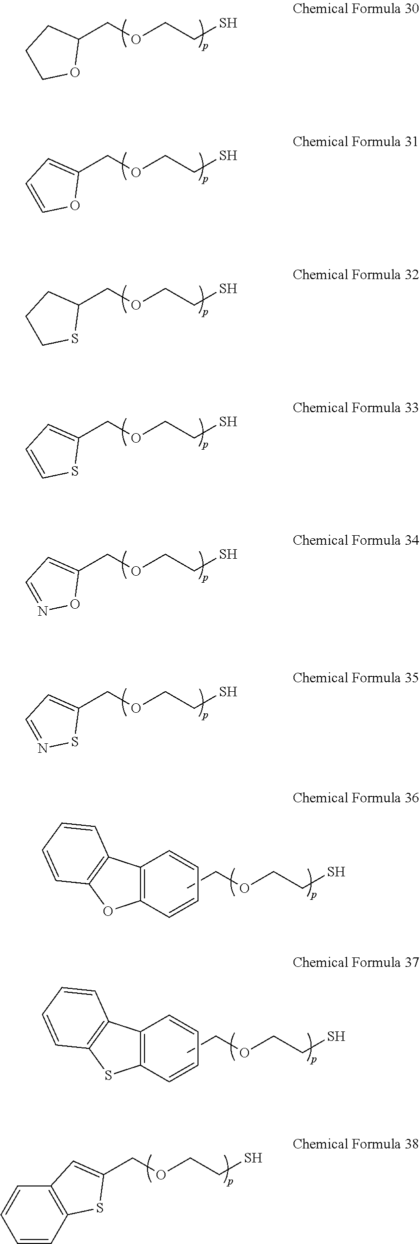

In Chemical Formulas 30 to 38,
p may be an integer from 1 to 100.

The surface-modifying material may be represented by Chemical Formula 40.

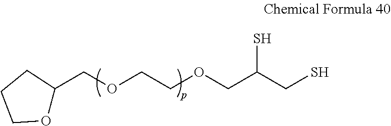

In Chemical Formula 40,
p may be an integer from 1 to 100.

The curable composition may be a solvent-free curable composition.

Based on a total amount of the solvent-free curable composition, the solvent-free curable composition may include about 5 wt % to about 60 wt % of the quantum dots; and about 40 wt % to about 95 wt % of the polymerizable compound.

The curable composition may further include a polymerization initiator, a light diffusing agent, a polymerization inhibitor, or a combination thereof.

The light diffusing agent may include barium sulfate, calcium carbonate, titanium dioxide, zirconia, or a combination thereof.

The curable composition may further include a solvent.

The curable composition may include about 1 wt % to about 40 wt % of the quantum dots; about 1 wt % to about 20 wt % of the polymerizable compound; and about 40 wt % to about 80 wt % of the solvent based on a total weight of the curable composition.

The curable composition may further include malonic acid; 3-amino-1,2-propanediol; a silane-based coupling agent; a leveling agent; a fluorine-based surfactant; or a combination thereof.

Another embodiment provides a cured layer produced utilizing the curable composition.

Another embodiment provides a display device including the cured layer.

Some embodiments of the present disclosure are included in the following detailed description.

By surface-modifying the quantum dots in the quantum dot-containing curable composition with a quantum dot surface-modifying material having a composition that has not been previously available, light resistance of the quantum dot-containing curable composition may be improved.

### DETAILED DESCRIPTION

Hereinafter, embodiments of the present disclosure are described in more detail. However, these embodiments serve as only as examples, the present disclosure is not limited thereto and, rather the present disclosure is defined by the scope of claims. In this regard, the present embodiments may have different forms and should not be construed as being limited to the descriptions set forth herein, and it is to be appreciated that all changes, equivalents, and substitutes that do not depart from the spirit and technical scope are encompassed in the present disclosure.

Unless otherwise defined, all chemical names, technical and scientific terms, and terms defined in common dictionaries should be interpreted as having meanings consistent with the context of the related art, and should not be interpreted in an ideal or overly formal sense. It will be understood that, although the terms first, second, and/or the like may be used herein to describe various elements, these elements should not be limited by these terms. These terms are only used to distinguish one element from another element. Thus, a first element could be termed a second element without departing from the teachings of the present disclosure. Similarly, a second element could be termed a first element.

As used herein, expressions such as “at least one of,” “one of,” “at least one selected from among,” and “selected from among,” if (e.g., when) preceding a list of elements, modify the entire list of elements and do not modify the individual elements of the list. As utilized herein, the expressions “at least one of A, B, or C”, “one of A, B, C, or a combination thereof” and “one of A, B, C, and a combination thereof” refer to each component and a combination thereof (e.g., A; B; A and B; A and C; B and C; or A, B, and C). For example, “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As utilized herein, alternative language such as “or” is not to be construed as an exclusive meaning, for example, “A or B” is construed to include A, B, A+B, and/or the like. Similarly, the term “and/or” includes any and all combinations of one or more of the associated listed items. The symbol “/” utilized herein may be interpreted as “and” or “or” according to the context.

In the present specification It will be understood that if (e.g., when) an element such as a layer, film, region, or substrate is referred to as being “on” another element, it may be directly on the other element or intervening elements may also be present. In contrast, if (e.g., when) an element is referred to as being “directly on” another element, there are no intervening elements present.

As utilized herein, it is to be understood that the terms such as “including,” “includes,” “include,” “having,” “has,” “have,” “comprises,” “comprise,” and/or “comprising” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added. The term “combination thereof may include a mixture, a laminate, a complex, a copolymer, an alloy, a blend, a reactant of constituents.

As utilized herein, singular forms such as “a,” “an,” and “the” are intended to include the plural forms as well, unless the context clearly indicates otherwise.

As utilized herein, the terms “use,” “using,” and “used” may be considered synonymous with the terms “utilize,” “utilizing,” and “utilized,” respectively.

The term “may” will be understood to refer to “one or more embodiments of the present disclosure,” some of which include the described element and some of which exclude that element and/or include an alternate element.

In this context, “consisting essentially of” means that any additional components will not materially affect the chemical, physical, optical or electrical properties of the semiconductor film.

### Definitions

As utilized herein, if (e.g., when) a specific definition is not otherwise provided, “alkyl group” refers to a C1 to C20 alkyl group, “alkenyl group” refers to a C2 to C20 alkenyl group, “cycloalkenyl group” refers to a C3 to C20 cycloalkenyl group, “heterocycloalkenyl group” refers to a C3 to C20 heterocycloalkenyl group, “aryl group” refers to a C6 to C20 aryl group, “arylalkyl group” refers to a C6 to C20 arylalkyl group, “alkylene group” refers to a C1 to C20 alkylene group, “arylene group” refers to a C6 to C20 arylene group, “alkylarylene group” refers to a C6 to C20 alkylarylene group, “heteroarylene group” refers to a C3 to C20 heteroarylene group, and “alkoxylene group” refers to a C1 to C20 alkoxylene group.

As utilized herein, if (e.g., when) a specific definition is not otherwise provided, “substituted” refers to replacement of at least one hydrogen atom by a substituent selected from among a halogen atom (F, Cl, Br, or I), a hydroxy group, a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, and/or a combination thereof.

As utilized herein, if (e.g., when) a specific definition is not otherwise provided, “hetero” refers to inclusion of at least one heteroatom of N, O, S, or P, in the chemical formula.

As utilized herein, if (e.g., when) a specific definition is not otherwise provided, “(meth)acrylate” refers to both (e.g., simultaneously) “acrylate” and “methacrylate,” and “(meth)acrylic acid” refers to “acrylic acid” and “methacrylic acid.”

As utilized herein, if (e.g., when) a specific definition is not otherwise provided, the term “combination” refers to mixing or copolymerization.

In the present specification, if (e.g., when) a definition is not otherwise provided, hydrogen is bonded at the position if (e.g., when) a chemical bond is not drawn in chemical formula where supposed to be given.

In the present disclosure, if (e.g., when) dots or particles are spherical, the term “diameter” indicates a particle diameter or an average particle diameter, and it (e.g., when) the dots or particles are non-spherical, the term “diameter” indicates a major axis length or an average major axis length. In some embodiments, the average particle diameter may be measured by a method well suitable to those skilled in the art, for example, may be measured by a particle size analyzer, or may be measured by a transmission electron microscopic image or a scanning electron microscopic image. In some embodiments, it is possible to obtain an average particle diameter value by measuring utilizing a dynamic light scattering method, performing data analysis, counting the number of particles for each particle size range, and calculating from this. As utilized herein, if (e.g., when) a definition is not otherwise provided, the average particle diameter may refer to a diameter (D50) of particles having a cumulative volume of 50 vol % in a particle size distribution.

In some embodiments, in the present specification, if (e.g., when) a definition is not otherwise provided, “*” or “*” refers to a linking point with the same or different atom or chemical formula. For example, “*” may be a linking point with a different atom, a same chemical formula, or a different chemical formula

### Curable Composition

A quantum dot-containing curable composition according to the present disclosure may utilize a surface-modifying material with a novel structure to surface-modify the quantum dot, thereby achieving relatively high light resistance when compared with a comparable quantum dot-containing curable composition.

According to the recent trend in the display field where a light source is being replaced from organic light emitting diodes (OLED) to micro light emitting diodes (LED), light resistance of a film mounted inside the display becomes more important than ever. Accordingly, light resistance of a cured layer formed by curing the quantum dot-containing curable composition also becomes very important to improve, but a comparable quantum dot surface-modifying material alone fails to provide (e.g., in securing) excellent or suitable film light resistance as required (e.g., not enough) to be utilized for the micro LED light source.

In general, in order to improve a curing rate of the quantum dot-containing curable composition, a relatively high-sensitivity initiator or a multi-functional monomer, and/or the like are additionally utilized. Comparable technology in the related arts, which select a specific configuration, may improve one characteristic among several (e.g., all) characteristics of the quantum dot-containing curable composition (e.g., such as dispersion, heat resistance, and the curing rate) but simultaneously deteriorate the other characteristics excluding the improved characteristic. In other words, regarding the characteristics of the quantum dot-containing curable composition, there has been no suitable technology for a quantum dot-containing curable composition capable of providing (e.g., maintaining) relatively low viscosity and concurrently or simultaneously providing (e.g., realizing) relatively high light resistance.

For example, the technology suitable in the state of the art (e.g., so far) includes a method of encapsulating the surfaces of the quantum dots with a polymer including a heat-resistant functional group, a siloxane-based organic material, or a silane-based (e.g., tetraethyl orthosilicate (TEOS), and/or the like) organic material, and/or the like; or encapsulating the surfaces of the quantum dots with aluminum, titanium, or an oxide thereof. In some embodiments, attempts have recently been made to concurrently (e.g., simultaneously) increase luminance and durability by doping a small amount of a transition metal (Cu, Mg, and/or the like) component in the quantum dot synthesis.

However, these methods as described are still under the early stages of academic study and far away from being ready to actually apply to a display.

Accordingly, the present disclosure relates to well-tested and repeatedly conducted research that provides (e.g., completes) a curable composition having relatively high light efficiency and excellent or suitable light resistance reliability. For example, a curable composition according to one or more embodiments includes (A) quantum dots including at least one functional group selected from among functional groups represented by Chemical Formulas 1, 2-1, 2-2, and 2-3; and (B) a polymerizable compound.

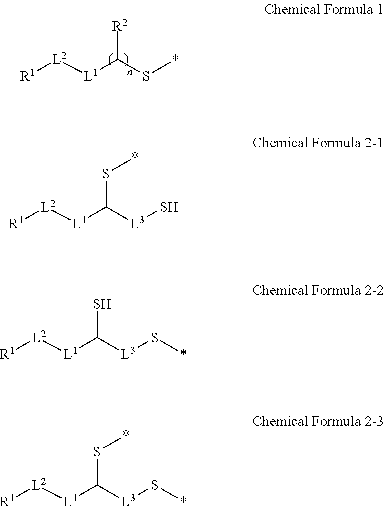

In Chemical Formulas 1, 2-1, 2-2, and 2-3,
L¹ may be a single bond, a substituted or unsubstituted C1 to C20 alkylene group, an ether group (*—O—*), *—(X-L^{a})-* (wherein X may be an oxygen atom or a sulfur atom, and L^{a} may be a substituted or unsubstituted C1 to C10 alkylene group) or a combination thereof,
L² and L³ may each independently be a single bond or a substituted or unsubstituted C1 to C20 alkylene group,
R¹ may be a substituted or unsubstituted heterocyclic group, and
R² may be a hydrogen atom or a substituted or unsubstituted C1 to C20 alkyl group,
n may be an integer of 0 or 1, and
“*” may be a linking point with a different atom, a same chemical formula, or a different chemical formula.

Hereinafter, each component included in (e.g., constituting) the curable composition according to one or more embodiments is described in more detail.

### Quantum Dots

The most suitable or efficient ligand capable of passivating the surfaces of the quantum dots as an organic material ligand is a ligand having a thiol group. In contrast, a carboxylic acid-type or kind of (e.g., a carboxylic acid) ligand (e.g., ester group) has relatively weak interaction with the surfaces of the quantum dots, and a phosphoric acid-type or kind of (e.g., a phosphoric acid) ligand may provide (e.g., has) sufficient dispersibility of the quantum dots but may also (e.g., create a problem of) lowering efficiency (e.g., efficiency in causing color changes).

Because display technologies have been developed from liquid crystal display (LCD) in the past to organic light emitting diodes (OLED), nano emissive displays (NED), and recent micro light emitting diodes (LED), which gradually increase intensity of blue light, the durability (particularly light resistance) of the quantum dots also should or needs to be significantly improved, e.g., compared with the current level.

Accordingly, the present disclosure is to apply a monodentate thiol ligand or a bidentate thiol ligand to effectively passivate the surface of quantum dots, wherein the ligand is structurally controlled or selected to necessarily have a heterocyclic group substituted at its terminal end but to exclude an (e.g., not include any) ester group (*—COO—*) from its linking group. For example, if (e.g., when) a quantum dot-containing curable composition surface-modified with the ligand is loaded as a single film on a display panel, even though exposed to strong blue light such as micro LED for a long time, the quantum dot-containing curable composition may maintain initial light efficiency and have very excellent or suitable light resistance.

For example, the heterocyclic group may include a nitrogen atom, an oxygen atom, a sulfur atom, or a combination thereof.

For example, the heterocyclic group may be represented by any one of Chemical Formulas H-1 to H-12, but the type or kind of the heterocyclic group is not limited thereto.

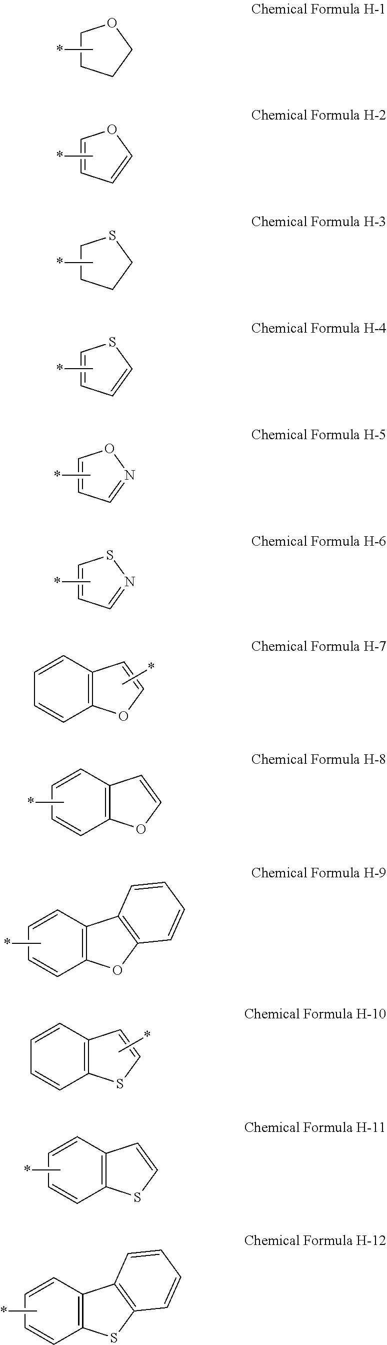

For example, the functional group represented by Chemical Formula 1 may be represented by any one of Chemical Formulas 1A to 1C, but is not necessarily limited thereto.

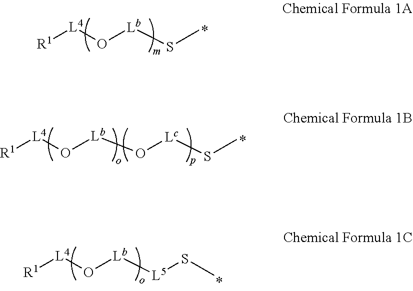

In Chemical Formulas 1A to 1C,
L⁴ is a single bond or a substituted or unsubstituted C1 to C20 alkylene group,
L⁵, L^{b}, and L^{c} may each independently be a substituted or unsubstituted C1 to C20 alkylene group,
R¹ is a substituted or unsubstituted heterocyclic group, and
m, o, and p may each independently be an integer of 1 to 100.

For example, the functional groups represented by Chemical Formulas 2-1 to 2-3 may be each represented by any one of Chemical Formulas 2A to 2F, but are not necessarily limited thereto.

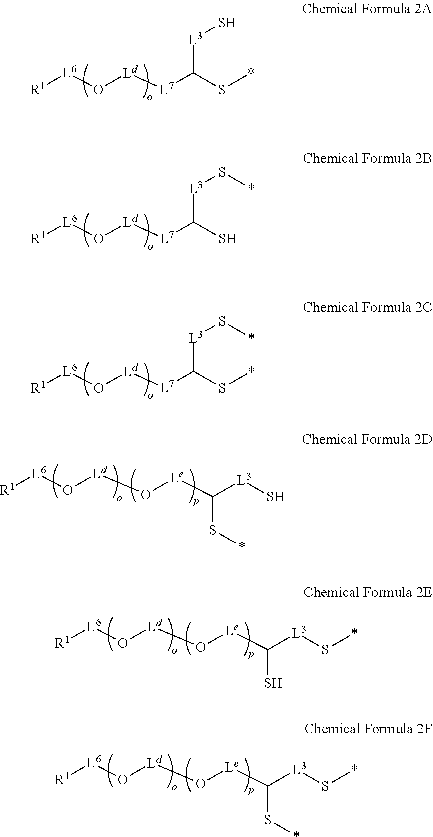

In Chemical Formulas 2A to 2F, L³, L⁷, and L⁶ may each independently be a single bond or a substituted or unsubstituted C1 to C20 alkylene group,
L^{d} and L^{e} may each independently be a substituted or unsubstituted C1 to C20 alkylene group,
R¹ is a substituted or unsubstituted heterocyclic group, and
o and p may each independently be an integer of 1 to 100.

For example, a functional group having a heterocyclic group at a terminal end linked to the surface of the quantum dots according to one or more embodiments may be represented by any one of Chemical Formulas 10 to 18 and Chemical Formulas 20 to 22, but is not necessarily limited thereto.

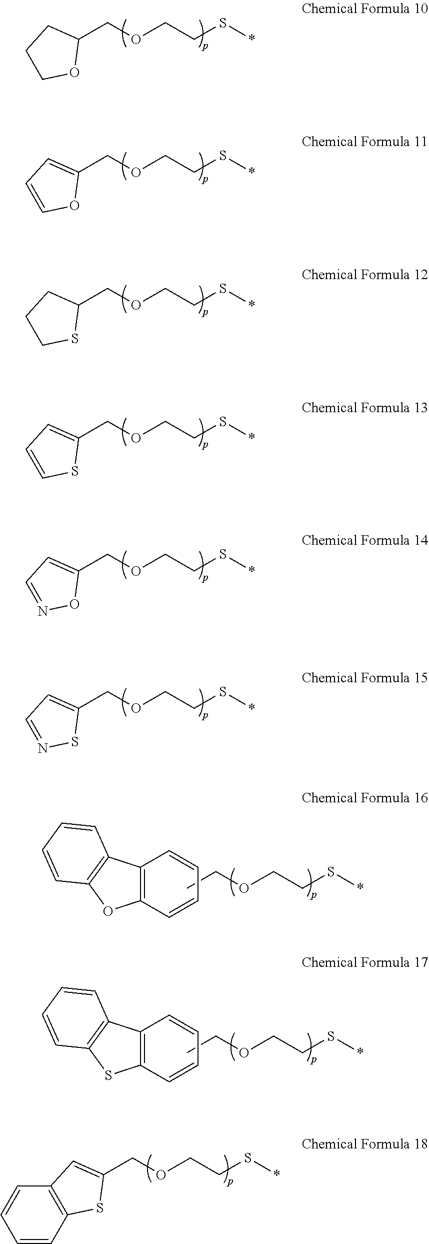

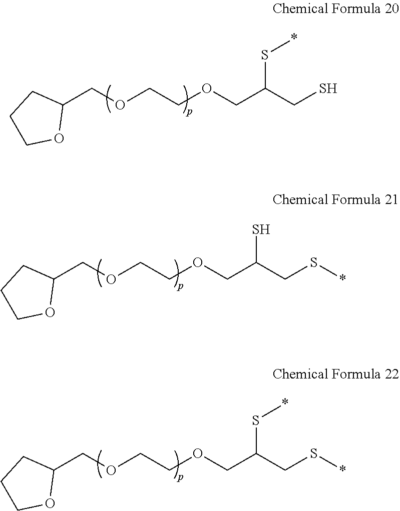

In Chemical Formulas 10 to 18 and Chemical Formulas 20 to 22,
p is an integer from 1 to 100.

On the other hand, the (A) quantum dots including at least one functional group selected from among the functional groups represented by Chemical Formulas 1, 2-1, 2-2, and 2-3 may be quantum dots surface-modified with at least one surface-modifying material selected from among compounds represented by Chemical Formulas 3 and 4.

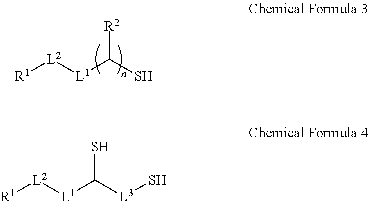

In Chemical Formulas 3 and 4,
L¹ is a single bond, a substituted or unsubstituted C1 to C20 alkylene group, an ether group (*—O—*), *—(X-L^{a})-* (wherein X is an oxygen atom or a sulfur atom, and L^{a} is a substituted or unsubstituted C1 to C10 alkylene group) or a combination thereof,
L² and L³ may each independently be a single bond or a substituted or unsubstituted C1 to C20 alkylene group,
R¹ is a substituted or unsubstituted heterocyclic group, and
R² is a hydrogen atom or a substituted or unsubstituted C1 to C20 alkyl group, and
n is an integer of 0 or 1.

For example, the curable composition according to one or more embodiments includes (A) surface-modified quantum dots with a surface-modifying material (i.e., quantum dots surface-modified with a surface-modifying material); and (B) a polymerizable compound, and the surface-modifying material includes at least one compound that is selected from among compounds represented by Chemical Formulas 3 and 4.

The heterocyclic group may be as described herein.

For example, the compound represented by Chemical Formula 3 may be represented by any one of Chemical Formulas 3A to 3C, but is not necessarily limited thereto.

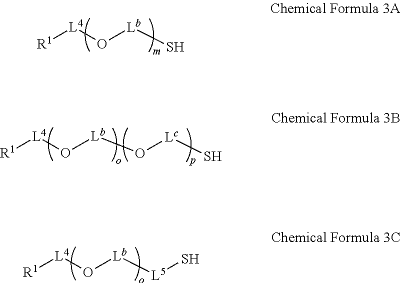

In Chemical Formulas 3A to 3C,
L⁴ is a single bond or a substituted or unsubstituted C1 to C20 alkylene group,
L⁵, L^{b}, and L^{c} may each independently be a substituted or unsubstituted C1 to C20 alkylene group,
R¹ is a substituted or unsubstituted heterocyclic group, and
m, o, and p may each independently be an integer of 1 to 100.

For example, the compound represented by Chemical Formula 4 may each be represented by any one of Chemical Formulas 4A and/or 4B, but are not necessarily limited thereto.

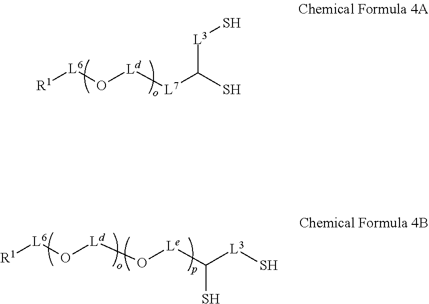

In Chemical Formulas 4A to 4B,
L³, L⁷, and L⁶ may each independently be a single bond or a substituted or unsubstituted C1 to C20 alkylene group,
L^{d} and L^{e} may each independently be a substituted or unsubstituted C1 to C20 alkylene group,
R¹ is a substituted or unsubstituted heterocyclic group, and
o and p may each independently be an integer of 1 to 100.

For example, the surface-modifying material may be represented by any one of Chemical Formulas 30 to 38 and/or Chemical Formula 40, but is not necessarily limited thereto.

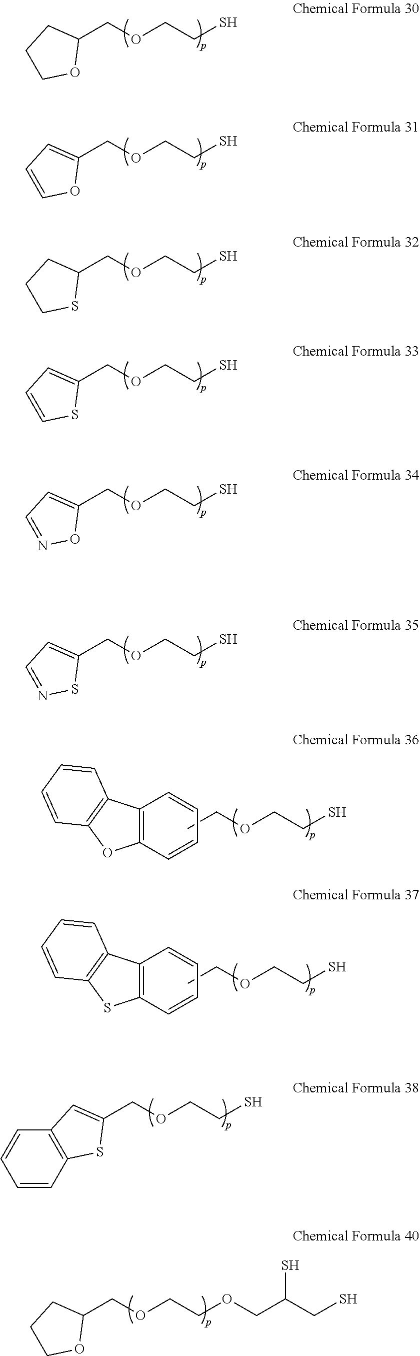

In Chemical Formulas 30 to 38 and Chemical Formula 40,
p is an integer from 1 to 100.

If (e.g., when) the surface-modified quantum dots with a surface-modifying material (i.e., quantum dots surface-modified with the surface-modifying material) are added to a polymerizable compound as described herein and stirred, a very transparent dispersion may be obtained, which is a criterion for confirming that the surface-modification of the quantum dots is very good or suitable.

For example, the quantum dots may have a maximum fluorescence emission wavelength at about 500 nanometer (nm) to about 680 nm.

For example, if (e.g., when) the curable composition according to one or more embodiments is a solvent-free curable composition, an amount of the quantum dots may be about 5 wt % to about 60 wt %, for example about 10 wt % to about 60 wt %, for example about 20 wt % to about 60 wt %, for example about 30 wt % to about 50 wt %. If (e.g., when) the quantum dots are included within the range, high light retention and light efficiency can be achieved, (e.g., even after curing).

For example, if (e.g., when) the curable composition according to one or more embodiments is a curable composition including a solvent, the quantum dots may be included in an amount of about 1 wt % to about 40 wt %, for example about 3 wt % to about 30 wt %, based on a total amount of the curable composition. If (e.g., when) the quantum dots are included within the disclosed range, the light conversion rate is improved and pattern characteristics and development characteristics are not impaired, so that excellent or suitable processability may be obtained.

Until now, a quantum dot-containing curable composition (ink) may have been developed toward specializing thiol-based binders or monomers having good or suitable compatibility with quantum dots, and furthermore, their commercialization may have been made.

For example, the quantum dots absorb light in a wavelength region of about 360 nm to about 780 nm, for example about 400 nm to about 780 nm and emits fluorescence in a wavelength region of about 500 nm to about 700 nm, for example about 500 nm to about 580 nm, or emits fluorescence in a wavelength region of about 600 nm to about 680 nm. For example, the quantum dots may have a maximum fluorescence emission wavelength (fluorescence λₑₘ) at about 500 nm to about 680 nm.

1 The quantum dots may each independently have a full width at half maximum (FWHM) of about 20 nm to about 100 nm, for example about 20 nm to about 50 nm. If (e.g., when) the quantum dots have a full width at half maximum (FWHM) of the ranges disclosed herein, color reproducibility is increased if (e.g., when) utilized as a color material in a color filter capable of (e.g., due to) high color purity.

The quantum dots may each independently be an organic material, an inorganic material, or a hybrid (mixture) of an organic material and an inorganic material.

The quantum dots may each independently be composed of a core and a shell around (e.g., surrounding) the core. For example, the core and the shell may each independently have a structure of a core, core/shell, core/first shell/second shell, alloy, alloy/shell, and/or the like. In some embodiments, the structures may be composed of Group II-IV elements, Group III-V elements, and/or the like, but are not limited thereto.

For example, the core may include at least at least one material selected from among CdS, CdSe, CdTe, ZnS, ZnSe, ZnTe, HgS, HgSe, HgTe, GaN, GaP, GaAs, InP, InAs, and an alloy thereof, but is not necessarily limited thereto. The shell around (e.g., surrounding) the core may include at least at least one material selected from among CdSe, ZnSe, ZnS, ZnTe, CdTe, PbS, TiO, SrSe, HgSe, and an alloy thereof, but is not necessarily limited thereto.

In one or more embodiments, because an interest in an environmental impact has been recently much increased over the whole world, and a restriction of a toxic material also has been fortified, the core may be a cadmium-free light emitting material (InP/ZnS, InP/ZnSe/ZnS, and/or the like), but is not necessarily limited thereto. For example, the cadmium-free light emitting material may have relatively little (e.g., low) quantum efficiency (quantum yield) but may be environmentally-friendly as compared to (e.g., instead of) a light emitting material having a cadmium-based core.

In the case of the quantum dots of the core/shell structure, an entire size including the shell (an average particle diameter) may be about 1 nm to about 15 nm, for example, about 5 nm to about 15 nm.

For example, the quantum dots may each independently include red quantum dots, green quantum dots, or a combination thereof. The red quantum dots may each independently have an average particle diameter of about 10 nm to about 15 nm. The green quantum dots may each independently have an average particle diameter of about 5 nm to about 8 nm.

On the other hand, for dispersion stability of the quantum dot, the curable composition according to one or more embodiments may further include a dispersant. The dispersant promotes (e.g., helps) substantially uniform dispersibility of light conversion materials such as quantum dots in the curable composition and may include a non-ionic, anionic, or cationic dispersant. For example, the dispersant may be polyalkylene glycol or esters thereof, a polyoxy alkylene, a polyhydric alcohol ester alkylene oxide addition product, an alcohol alkylene oxide addition product, a sulfonate ester, a sulfonate salt, a carboxylate ester, a carboxylate salt, alkyl amide alkylene oxide addition product, alkyl amine and/or the like, and they may be utilized alone or in a mixture of two or more. The dispersant may be utilized in an amount of about 0.1 wt % to about 100 wt %, for example about 10 wt % to about 20 wt % based on a solid content (e.g., amount) of the light conversion material such as quantum dots.

### Polymerizable Compound

The curable composition according to one or more embodiments may include a polymerizable compound, and the polymerizable compound may have a carbon-carbon double bond at its terminal end.

The polymerizable compound having the carbon-carbon double bond at the terminal end may be included in an amount of about 40 wt % to about 95 wt %, for example, about 50 wt % to about 90 wt %, based on a total amount of the solvent-free curable composition. If (e.g., when) the polymerizable compound having the carbon-carbon double bond at the terminal end is included within the ranges, a solvent-free curable composition having a viscosity that enables ink-jetting may be prepared and the quantum dots in the prepared solvent-free curable composition may have improved dispersibility, thereby improving optical characteristics.

For example, the polymerizable compound having the carbon-carbon double bond at the terminal end may have a molecular weight of about 170 g/mol to about 1,000 g/mol. If (e.g., when) the polymerizable compound having the carbon-carbon double bond at the terminal end has a molecular weight within the range, it may be advantageous for ink-jetting because it does not increase a viscosity of the composition without hindering the optical characteristics of the quantum dots.

For example, the polymerizable compound having the carbon-carbon double bond at the terminal end may be represented by Chemical Formula 6, but is not necessarily limited thereto.

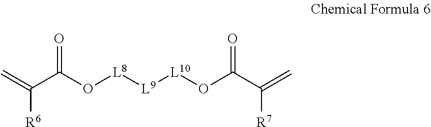

In Chemical Formula 6,
R⁶ and R⁷ may each independently be a hydrogen atom or a substituted or unsubstituted C1 to C10 alkyl group,
L⁸ and L¹⁰ may each independently be a single bond or a substituted or unsubstituted C1 to C10 alkylene group,
L⁹ is a substituted or unsubstituted C1 to C10 alkylene group, a substituted or unsubstituted C3 to C20 cycloalkylene group, or an ether group (*—O—*).

For example, the polymerizable compound having a carbon-carbon double bond at the terminal end may be represented by Chemical Formula 6-1 or 6-2, but is not necessarily limited thereto.

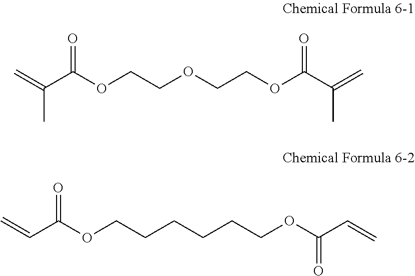

For example, the polymerizable compound having the carbon-carbon double bond at the terminal end may further include ethylene glycoldiacrylate, triethylene glycoldiacrylate, 1,4-butanedioldiacrylate, 1,6-hexanedioldiacrylate, neopentylglycoldiacrylate, pentaerythritoldiacrylate, pentaerythritoltriacrylate, dipentaerythritoldiacrylate, dipentaerythritoltriacrylate, dipentaerythritolpentaacrylate, pentaerythritolhexaacrylate, bisphenol A diacrylate, trimethylolpropanetriacrylate, novolac epoxyacrylate, ethylene glycoldimethacrylate, triethylene glycoldimethacrylate, propylene glycoldimethacrylate, 1,4-butanedioldimethacrylate, 1,6-hexanedioldimethacrylate, or a combination thereof in addition to the aforementioned compound of Chemical Formula 6-1 or 6-2.

In some embodiments, together with the polymerizable compound having the carbon-carbon double bond at the terminal end, a generally-utilized monomer of a comparable thermosetting or photocurable composition may be further included. For example, the monomer may further include an oxetane-based compound such as bis[1-ethyl(3-oxetanyl)]methyl ether, and/or the like.

In some embodiments, if (e.g., when) the curable composition includes a solvent, based on a total amount of the curable composition, the polymerizable compound may be included in an amount of about 1 wt % to about 20 wt %, about 1 wt % to about 15 wt %, for example, about 5 wt % to about 15 wt %. If (e.g., when) the polymerizable compound is included within the disclosed range, optical characteristics of the quantum dots may be improved.

### Light Diffusing Agent

The curable composition according to one or more embodiments may further include a light diffusing agent.

For example, the light diffusing agent may include barium sulfate (BaSO₄), calcium carbonate (CaCO₃), titanium dioxide (TiO₂), zirconia (ZrO₂), or a combination thereof.

The light diffusing agent may reflect unabsorbed light in the aforementioned quantum dots and may allow the quantum dots to absorb the reflected light again. For example, the light diffusing agent may increase an amount of light absorbed by the quantum dots and increase light conversion efficiency of the curable composition.

The light diffusing agent may have an average particle diameter (D₅₀) of about 150 nm to about 250 nm, and specifically about 180 nm to about 230 nm. If (e.g., when) the average particle diameter of the light diffusing agent is within the ranges, it may have an improved (e.g., better) light diffusing effect and increase light conversion efficiency.

The light diffusing agent may be included in an amount of about 1 wt % to about 20 wt %, for example, about 2 wt % to about 15 wt %, for example, about 3 wt % to about 10 wt % based on a total amount of the curable composition. If (e.g., when) the light diffusing agent is included in an amount of less than about 1 wt % based on a total amount of the curable composition, it is difficult to expect a light conversion efficiency improvement effect due to the utilize of the light diffusing agent, while if (e.g., when) it is included in an amount of greater than about 20 wt %, there is a possibility that the quantum dots may be precipitated.

### Polymerization Initiator

The curable composition according to one or more embodiments may further include a polymerization initiator, for example, a photopolymerization initiator, a thermal polymerization initiator, or a combination thereof.

The photopolymerization initiator is a generally-utilized initiator for a photosensitive resin composition, for example an acetophenone-based compound, a benzophenone-based compound, a thioxanthone-based compound, a benzoin-based compound, a triazine-based compound, an oxime-based compound, an aminoketone-based compound, and/or the like, but is not necessarily limited thereto.

Examples of the acetophenone-based compound may be 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and/or the like.

Examples of the benzophenone-based compound may be benzophenone, benzoyl benzoate, benzoyl methyl benzoate, 4-phenyl benzophenone, hydroxybenzophenone, acrylated benzophenone, 4,4′-bis(dimethyl amino)benzophenone, 4,4′-bis(diethylamino) benzophenone, 4,4′-dimethylaminobenzophenone, 4,4′-dichlorobenzophenone, 3,3′-dimethyl-2-methoxybenzophenone, and/or the like.

Examples of the thioxanthone-based compound may be thioxanthone, 2-methylthioxanthone, isopropyl thioxanthone, 2,4-diethyl thioxanthone, 2,4-diisopropyl thioxanthone, 2-chlorothioxanthone, and/or the like.

Examples of the benzoin-based compound may be benzoin, benzoin methyl ether, benzoin ethyl ether, benzoin isopropyl ether, benzoin isobutyl ether, benzyldimethylketal, and/or the like.

Examples of the triazine-based compound may be 2,4,6-trichloro-s-triazine, 2-phenyl-4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl-4,6-bis(trichloro methyl)-s-triazine, bis(trichloromethyl)-6-styryl-s-triazine, 2-(naphtho1-yl)-4,6-bis(trichloromethyl)-s-triazine, 2-(4-methoxynaphtho1-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and/or the like.

Examples of the oxime-based compound may be O-acyloxime-based compound, 2-(O-benzoyloxime)-1-[4-(phenylthio)phenyl]-1,2-octandione, 1-(O-acetyloxime)-1-[9-ethyl-6-(2-methylbenzoyl)-9H-carbazol-3-yl]ethanone, O-ethoxycarbonyl-α-oxyamino-1-phenylpropan-1-one, and/or the like. Specific examples of the O-acyloxime-based compound may be 1,2-octandione, 2-dimethylamino-2-(4-methylbenzyl)-1-(4-morpholin-4-yl-phenyl)-butan-1-one, 1-(4-phenylsulfanyl phenyl)-butane-1,2-dione-2-oxime-O-benzoate, 1-(4-phenylsulfanyl phenyl)-octane-1,2-dione-2-oxime-O-benzoate, 1-(4-phenylsulfanyl phenyl)-octan-1-oneoxime-O-acetate, 1-(4-phenylsulfanyl phenyl)-butan-1-oneoxime-O-acetate, and/or the like.

Examples of the aminoketone-based compound may be 2-benzyl-2-dimethylamino-1-(4-morpholinophenyl)-butanone-1, and/or the like.

The photopolymerization initiator may further include a carbazole-based compound, a diketone-based compound, a sulfonium borate-based compound, a diazo-based compound, an imidazole-based compound, a diimidazole-based compound, and/or the like, besides the compounds.

The photopolymerization initiator may be utilized with a photosensitizer capable of initiating (e.g., causing) a chemical reaction by absorbing light and becoming excited and then, transferring (e.g., its) energy.

Examples of the photosensitizer may be tetraethylene glycol bis-3-mercapto propionate, pentaerythritol tetrakis-3-mercapto propionate, dipentaerythritol tetrakis-3-mercapto propionate, and/or the like.

Examples of the thermal polymerization initiator may be peroxide, specifically benzoyl peroxide, dibenzoyl peroxide, lauryl peroxide, dilauryl peroxide, di-tert-butyl peroxide, cyclohexane peroxide, methyl ethyl ketone peroxide, hydroperoxide (e.g., tert-butyl hydroperoxide, cumene hydroperoxide), dicyclohexyl peroxydicarbonate, 2,2-azo-bis(isobutyronitrile), t-butyl perbenzoate, and/or the like, for example 2,2′-azobis-2-methylpropinonitrile, but are not necessarily limited thereto and any of which is well suitable in the art may be utilized.

The polymerization initiator may be included in an amount of about 0.1 wt % to about 5 wt %, for example about 1 wt % to about 4 wt % based on a total amount of the curable composition. If (e.g., when) the polymerization initiator is included in the ranges, it is possible to obtain excellent or suitable reliability due to sufficient curing during exposure or thermal curing and to prevent or reduce deterioration of transmittance due to non-reaction initiators, thereby preventing or reducing deterioration of optical characteristics of the quantum dots.

### Binder Type Resin

The curable composition according to one or more embodiments may further include a binder resin.

The binder resin may include an acrylic resin, a cardo-based resin, an epoxy resin, or a combination thereof.

The acrylic resin may be a copolymer of a first ethylenic unsaturated monomer and a second ethylenic unsaturated monomer that is copolymerizable therewith, and may be a resin including at least one acryl-based repeating unit.

Specific examples of the acrylic resin may be polybenzylmethacrylate, a (meth)acrylic acid/benzylmethacrylate copolymer, a (meth)acrylic acid/benzylmethacrylate/styrene copolymer, a (meth)acrylic acid/benzylmethacrylate/2-hydroxyethylmethacrylate copolymer, a (meth)acrylic acid/benzylmethacrylate/styrene/2-hydroxyethylmethacrylate copolymer, and/or the like, but are not limited thereto, and may be utilized alone or as a mixture of two or more.

A weight average molecular weight of the acrylic resin may be about 5,000 g/mol to about 15,000 g/mol. If (e.g., when) the acrylic resin has a weight average molecular weight within the ranges, close contacting properties to a substrate, physical and chemical properties are improved, and a viscosity is appropriate or suitable.

An acid value of the acrylic resin may be about 80 mg KOH/g to about 130 mg KOH/g. If (e.g., when) the acrylic resin has an acid value within the ranges, excellent or suitable resolution of a pixel may be obtained.

The cardo-based resin may be one utilized in a comparable curable resin (or photosensitive resin) composition, for example, one suggested in Korean Patent Publication No. 10-2018-0067243 may be utilized, but is not limited thereto, the entire content of which is incorporated herein by reference.

The cardo-based resin may be, for example prepared by mixing at least two of a fluorene-containing compound such as 9,9-bis(4-oxiranylmethoxyphenyl) fluorene; an anhydride compound such as benzenetetracarboxylic acid dianhydride, naphthalenetetracarboxylic acid dianhydride, biphenyltetracarboxylic acid dianhydride, benzophenonetetracarboxylic acid dianhydride, pyromellitic dianhydride, cyclobutanetetracarboxylic acid dianhydride, perylenetetracarboxylic acid dianhydride, tetrahydrofurantetracarboxylic acid dianhydride, and tetrahydrophthalic anhydride; a glycol compound such as ethylene glycol, propylene glycol, and polyethylene glycol; an alcohol compound such as methanol, ethanol, propanol, n-butanol, cyclohexanol, and benzylalcohol; a solvent-based compound such as propylene glycol methylethylacetate, and N-methylpyrrolidone; a phosphorus compound such as triphenylphosphine; and an amine or ammonium salt compound such as tetramethylammonium chloride, tetraethylammonium bromide, benzyldiethylamine, triethylamine, tributylamine, or benzyl triethylammonium chloride.

A weight average molecular weight of the cardo-based binder resin may be about 500 g/mol to about 50,000 g/mol, for example about 1,000 g/mol to about 30,000 g/mol. If (e.g., when) the weight average molecular weight of the cardo-based binder resin is within the ranges, a satisfactory pattern may be formed without a residue during a production of a cured layer and without losing a film thickness during development of the curable composition.

If (e.g., when) the binder resin is a cardo-based resin, the curable composition including the same, particularly the photosensitive resin composition has excellent or suitable developability and sensitivity during photo-curing and thus, fine pattern-forming capability.

The epoxy resin may be a thermally polymerizable monomer or oligomer, and may include a compound having a carbon-carbon unsaturated bond and a carbon-carbon cyclic bond.

The epoxy resin may further include a bisphenol A epoxy resin, a bisphenol F epoxy resin, a phenol novolac epoxy resin, a cyclic aliphatic epoxy resin, and an aliphatic polyglycidyl ether, but is not necessarily limited thereto.

As commercially available products of the compounds, a bisphenyl epoxy resin may be YX4000, YX4000H, YL6121H, YL6640, or YL6677 of Yuka Shell Epoxy Co., Ltd.; a cresol novolac epoxy resin may be EOCN-102, EOCN-103S, EOCN-104S, EOCN-1020, EOCN-1025, and EOCN-1027 of Nippon Kayaku Co., Ltd. and EPIKOTE 180S75, and/or the like of Yuka Shell Epoxy Co., Ltd.; a bisphenol A epoxy resin may be EPIKOTE 1001, 1002, 1003, 1004, 1007, 1009, 1010, and 828 of Yuka Shell Epoxy Co., Ltd.; a bisphenol F epoxy resin may be EPIKOTE 807 and 834 of Yuka Shell Epoxy Co., Ltd.; a phenol novolac epoxy resin may be EPIKOTE 152, 154, or 157H65 of Yuka Shell Epoxy Co. and EPPN 201, 202 of Nippon Kayaku Co., Ltd. and EPPN 201, 202 of Nippon Kayaku Co., Ltd.; a cyclic aliphatic epoxy resin may be CY175, CY177, and CY179 of CIBA-GEIGY A.G Corp., ERL-4234, ERL-4299, ERL-4221 and ERL-4206 of U.C.C., Showdyne 509 of Showa Denko K.K., Araldite CY-182, CY-192 and CY-184 of CIBA-GEIGY A.G Corp., EPICLON 200 and 400 of Dainippon Ink & Chemicals Inc., EPIKOTE 871 and 872, and EP1032H60 of Yuka Shell Epoxy Co., Ltd., ED-5661 and ED-5662 of Celanese Coating Corporation; an aliphatic polyglycidylether may be EPIKOTE 190P and 191P of Yuka Shell Epoxy Co., Ltd., EPOLITE 100MF of Kyoeisha Yushi Kagaku Kogyo Co., Ltd., EPIOL TMP of Nihon Yushi K. K., and/or the like.

For example, if (e.g., when) the curable composition according to one or more embodiments is a solvent-free curable composition, the binder resin may be included in an amount of about 0.5 wt % to about 10 wt %, for example, about 1 wt % to about 5 wt %, based on a total amount of the curable composition. In this case, the heat resistance and the chemical resistance of the solvent-free curable composition may be improved, as well as the storage stability of the composition.

For example, if (e.g., when) the curable composition according to one or more embodiments is a curable composition including a solvent, the binder resin may be included in an amount of about 1 wt % to about 30 wt %, for example, about 3 wt % to about 20 wt %, based on a total amount of the curable composition. In this case, it may improve pattern characteristics, heat resistance, and chemical resistance.

### Other Additives

For stability and dispersion improvement of the quantum dot, the curable composition according to one or more embodiments may further include a polymerization inhibitor.

The polymerization inhibitor may include a hydroquinone-based compound, a catechol-based compound, or a combination thereof, but is not necessarily limited thereto. If (e.g., when) the curable composition according to one or more embodiments further includes the hydroquinone-based compound, the catechol-based compound, or the combination thereof, room temperature cross-linking during exposure after coating the curable composition may be prevented or reduced.

For example, the hydroquinone-based compound, the catechol-based compound, or the combination thereof may be hydroquinone, methyl hydroquinone, methoxyhydroquinone, t-butyl hydroquinone, 2,5-di-t-butyl hydroquinone, 2,5-bis(1,1-dimethylbutyl) hydroquinone, 2,5-bis(1,1,3,3-tetramethylbutyl) hydroquinone, catechol, t-butyl catechol, 4-methoxyphenol, pyrogallol, 2,6-di-t-butyl-4-methylphenol, 2-naphthol, tris(N-hydroxy-N-nitrosophenylaminato-O,O′)aluminum, or a combination thereof, but are not necessarily limited thereto.

The hydroquinone-based compound, the catechol-based compound, or the combination thereof may be utilized in a form of dispersion. The polymerization inhibitor in a form of dispersion may be included in an amount of about 0.001 wt % to about 3 wt %, for example about 0.01 wt % to about 2 wt % based on a total amount of the curable composition. If (e.g., when) the polymerization inhibitor is included in the ranges, degradation caused by passage of time at room temperature may be prevented or reduced (e.g., solved) and concurrently (e.g., simultaneously) sensitivity deterioration and surface delamination phenomenon may be prevented or reduced.

In some embodiments, the curable composition according to one or more embodiments may further include malonic acid; 3-amino-1,2-propanediol; a silane-based coupling agent; a leveling agent; a fluorine-based surfactant; or a combination thereof in order to improve heat resistance and reliability.

For example, the curable composition according to embodiment may further include a silane-based coupling agent having a reactive substituent such as a vinyl group, a carboxyl group, a methacryloxy group, an isocyanate group, an epoxy group, and/or the like in order to improve adhesion (e.g., close contacting properties) with a substrate.

Examples of the silane-based coupling agent may be trimethoxysilyl benzoic acid, γ-methacryl oxypropyl trimethoxysilane, vinyl triacetoxysilane, vinyl trimethoxysilane, γ-isocyanate propyl triethoxysilane, γ-glycidoxy propyl trimethoxysilane, β-epoxycyclohexyl)ethyltrimethoxysilane, and/or the like, and these may be utilized alone or in a mixture of two or more.

The silane-based coupling agent may be utilized in an amount of about 0.01 parts by weight to about 10 parts by weight based on 100 parts by weight of the curable composition. If (e.g., when) the silane-based coupling agent is included within the range, adhesion (e.g., close contacting properties), storage capability, and/or the like are improved.

In some embodiments, the curable composition may further include a surfactant, for example a fluorine-based surfactant as needed in order to improve coating properties and inhibit generation of spots, that is, improve leveling performance.

The fluorine-based surfactant may have a low weight average molecular weight of about 4,000 g/mol to about 10,000 g/mol, for example, about 6,000 g/mol to about 10,000 g/mol. In some embodiments, the fluorine-based surfactant may have a surface tension of about 18 millinewton per meter (mN/m) to about 23 mN/m (measured in a 0.1% polyethylene glycol monomethylether acetate (PGMEA) solution). If (e.g., when) the fluorine-based surfactant has a weight average molecular weight and a surface tension within the ranges, leveling performance may be further improved, and excellent or suitable characteristics may be provided if (e.g., when) slit coating by high-speed coating is applied. For example, film defects may be less readily generated by preventing or reducing a spot generation during the high-speed coating and suppressing a vapor generation.

Examples of the fluorine-based surfactant may be, BM-1000®, and BM-1100® (BM Chemie Inc.); MEGAFACE F 142D®, F 172®, F 173®, and F 183® Dainippon Ink Kagaku Kogyo Co., Ltd.); FULORAD FC-135®, FULORAD FC-170C®, FULORAD FC-430®, and FULORAD FC-431® (Sumitomo 3M Co., Ltd.); SURFLON S-112®, SURFLON S-113®, SURFLON S-131®, SURFLON S-141®, and SURFLON S-145® (ASAHI Glass Co., Ltd.); and SH-28PA®, SH-1900, SH-193®, SZ-6032®, and SF-8428®, and/or the like (Toray Silicone Co., Ltd.); F-482, F-484, F-478, F-554 and/or the like of DIC Co., Ltd.

The curable composition according to one or more embodiments may include a silicone-based surfactant in addition to the fluorine-based surfactant. Specific examples of the silicone-based surfactant may be TSF400, TSF401, TSF410, TSF4440, and/or the like of Toshiba silicone Co., Ltd., but are not limited thereto.

The surfactant may be included in an amount of about 0.01 parts by weight to about 5 parts by weight, for example about 0.1 parts by weight to about 2 parts by weight based on 100 parts by weight of the curable composition. If (e.g., when) the surfactant is included within the ranges, foreign materials are less produced in a sprayed composition.

The curable composition according to one or more embodiments may further include other additives such as an antioxidant, a stabilizer, and/or the like in a set or predetermined amount, unless properties are deteriorated.

### Solvent

The curable composition according to one or more embodiments may further include a solvent.

The solvent may, for example, include alcohols such as methanol, ethanol, and/or the like; glycol ethers such as ethylene glycol methylether, ethylene glycol ethylether, propylene glycol methylether, and/or the like; cellosolve acetates such as methyl cellosolve acetate, ethyl cellosolve acetate, diethyl cellosolve acetate, and/or the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, and/or the like; propylene glycol alkylether acetates such as propylene glycol monomethylether acetate, propylene glycol propylether acetate, and/or the like; ketones such as methylethylketone, cyclohexanone, 4-hydroxy-4-methyl-2-pentanone, methyl-n-propylketone, methyl-n-butylketone, methyl-n-amylketone, 2-heptanone, and/or the like; saturated aliphatic monocarboxylic acid alkyl esters such as ethyl acetate, n-butyl acetate, isobutyl acetate, and/or the like; lactate esters such as methyl lactate, ethyl lactate, and/or the like; hydroxy acetic acid alkyl esters such as methyl hydroxyacetate, ethyl hydroxyacetate, butyl hydroxyacetate, and/or the like; acetic acid alkoxyalkyl esters such as methoxymethyl acetate, methoxyethyl acetate, methoxybutyl acetate, ethoxymethyl acetate, ethoxyethyl acetate, and/or the like; 3-hydroxypropionic acid alkyl esters such as methyl 3-hydroxypropionate, ethyl 3-hydroxypropionate, and/or the like; 3-alkoxypropionic acid alkyl esters such as methyl 3-methoxypropionate, ethyl 3-methoxypropionate, ethyl 3-ethoxypropionate, methyl 3-ethoxypropionate, and/or the like; 2-hydroxypropionic acid alkyl ester such as methyl 2-hydroxypropionate, ethyl 2-hydroxypropionate, propyl 2-hydroxypropionate, and/or the like; 2-alkoxypropionic acid alkyl esters such as methyl 2-methoxypropionate, ethyl 2-methoxypropionate, ethyl 2-ethoxypropionate, methyl 2-ethoxypropionate, and/or the like; 2-hydroxy-2-methylpropionic acid alkyl esters such as methyl 2-hydroxy-2-methylpropionate, ethyl 2-hydroxy-2-methylpropionate, and/or the like; 2-alkoxy-2-methylpropionic acid alkyl esters such as methyl 2-methoxy-2-methylpropionate, ethyl 2-ethoxy-2-methylpropionate, and/or the like; esters such as 2-hydroxyethyl propionate, 2-hydroxy-2-methylethyl propionate, hydroxyethyl acetate, methyl 2-hydroxy-3-methylbutanoate, and/or the like; or ketonate esters such as ethyl pyruvate, and/or the like, and in addition, may be N-methylformamide, N,N-dimethyl formamide, N-methylformanilide, N-methylacetamide, N,N-dimethyl acetamide, N-methylpyrrolidone, dimethylsulfoxide, benzylethylether, dihexylether, acetylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, phenyl cellosolve acetate, and/or the like, but is not limited thereto.

For example, the solvent may be one or more glycol ethers such as ethylene glycol monoethylether, ethylene diglycolmethylethylether, and/or the like; ethylene glycol alkylether acetates such as ethyl cellosolve acetate, and/or the like; esters such as 2-hydroxy ethyl propionate, and/or the like; carbitols such as diethylene glycol monomethylether, and/or the like; propylene glycol alkylether acetates such as propylene glycol monomethylether acetate, propylene glycol propylether acetate, and/or the like; alcohols such as ethanol, and/or the like, or a combination thereof.

For example, the solvent may be a polar solvent including propylene glycol monomethylether acetate, dipropylene glycol methylether acetate, ethanol, ethylene glycoldimethylether, ethylenediglycolmethylethylether, diethylene glycoldimethylether, 2-butoxyethanol, N-methylpyrrolidine, N-ethylpyrrolidine, propylene carbonate, γ-butyrolactone, or a combination thereof.

The solvent may be included in an amount of about 40 wt % to about 80 wt %, for example, about 45 wt % to about 80 wt %, based on a total amount of the curable composition. If (e.g., when) the solvent is within the range, the solvent type or kind curable composition has appropriate or suitable viscosity and thus may have excellent or suitable coating property if (e.g., when) coated in a large area through spin-coating and slit-coating.

Another embodiment provides a cured layer produced utilizing the aforementioned curable composition, a color filter including the cured layer, and a display device including the color filter. For example, the display device may include a micro LED light source.

One of methods of producing the cured layer may include coating the curable composition and solvent type or kind curable composition on a substrate utilizing an ink-jet spraying method to form a pattern (S1); and curing the pattern (S2).

### (S1) Formation of Pattern

The curable composition may be coated to be about 0.5 micrometer (μm) to about 20 μm on a substrate in an ink-jet spraying method. The ink-jet spraying method may form a pattern by spraying a single color per each nozzle and thus repeating the spraying as many times as the needed number of colors, but the pattern may be formed by concurrently (e.g., simultaneously) spraying the needed number of colors through each ink-jet nozzle in order to reduce processes.

### (S2) Curing

The obtained pattern is cured to obtain a pixel. Herein, the curing method may be thermal curing or photocuring process. The thermal curing process may be performed at greater than or equal to about 100° C., desirably, in a range of about 100° C. to about 300° C., and more desirably, in a range of about 160° C. to about 250° C. The photocuring process may include irradiating an actinic ray such as a UV ray of about 190 nm to about 450 nm, for example about 200 nm to about 400 nm. As a light source utilized for irradiation, a low-pressure mercury lamp, high-pressure mercury lamp, ultra-high-pressure mercury lamp, metal halide lamp, argon gas laser, i-line, KrF, ArF, I—ArF, EUV, X-ray, electron beam, and/or the like may be utilized as needed.

In some embodiments, a method of producing the cured layer may include producing a cured layer utilizing the aforementioned curable composition or solvent type or kind of curable composition by a lithographic method as described herein.

### (1) Coating and Film Formation

The curable composition may be coated to have a desired or suitable thickness, for example, a thickness in a range of about 2 μm to about 10 μm, on a substrate which undergoes a set or predetermined pretreatment, utilizing a spin or slit coating method, a roll coating method, a screen-printing method, an applicator method, and/or the like. Then, the coated substrate may be heated at a temperature of about 70° C. to about 90° C. for about 1 minute to about 10 minutes to remove a solvent and to form a film.

### (2) Exposure

The resultant film may be irradiated by an actinic ray such as a UV ray of about 190 nm to about 450 nm, for example about 200 nm to about 400 nm after putting a mask with a set or predetermined shape to form a desired or suitable pattern. As a light source utilized for irradiation, a low-pressure mercury lamp, high-pressure mercury lamp, ultra-high-pressure mercury lamp, metal halide lamp, argon gas laser, i-line, KrF, ArF, I—ArF, EUV, X-ray, electron beam, and/or the like may be utilized as needed.

Exposure process uses, for example, a light dose of 500 millijoule per square centimeter (mJ/cm²) or less (with a 365 nm sensor) if (e.g., when) a high-pressure mercury lamp is utilized. However, the light dose may vary depending on types (kinds) of each component of the curable composition, its combination ratio, and a dry film thickness.

### (3) Development

After the exposure process, an alkali aqueous solution may be utilized to develop the exposed film by dissolving and removing an unnecessary part except the exposed part, forming an image pattern. In other words, if (e.g., when) the alkali developing solution is utilized for the development, an unexposed region may be dissolved, and an image color filter pattern may be formed.

### (4) Post-Treatment

The developed image pattern may be heated again or irradiated by an actinic ray and/or the like for curing, in order to accomplish excellent or suitable quality in terms of heat resistance, light resistance, close contacting properties, crack-resistance, chemical resistance, high strength, storage stability, and/or the like.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

A display device, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

Hereinafter, the present disclosure is illustrated in more detail with reference to examples. These examples, however, are not in any sense to be interpreted as limiting the scope of the present disclosure.

### EXAMPLES

### Synthesis of Surface-Modifying Materials

### Synthesis Example 1

A compound represented by Chemical Formula A was synthesized by putting 102 g of tetrahydrofurfuryl alcohol and 0.1 g of KOH in a high-pressure reactor and after increasing its internal temperature to 80° C., 176 g of ethylene oxide was slowly added thereto, while adjusting the internal pressure.

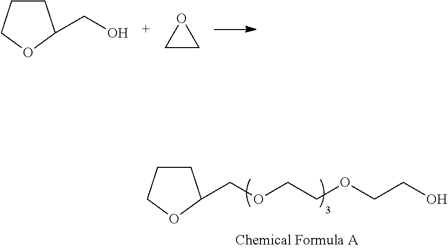

278 g of the compound represented by Chemical Formula A was put in a two-necked round bottom flask and sufficiently dissolved in 800 mL of THF. Subsequently, 44 g of NaOH and 100 mL of water were added thereto at 0° C. and then, sufficiently dissolved, until a transparent solution was obtained. Another solution prepared by dissolving 210 g of para-toluene sulfonic chloride in 300 mL of THF was slowly injected thereinto at 0° C. The injection proceeded for 2 hours, and then, the obtained mixture was stirred at room temperature (23° C.) for 12 hours. If (e.g., when) the reaction was completed, an excessive amount of methylene chloride was added thereto and then, stirred, and a NaHCO₃ saturated solution was added thereto and then, proceeded with extraction, titration, and moisture removal. After removing the solvent, drying in a dry oven was performed for 24 hours. 432 g of the dried product was put in a two necked round bottom flask and sufficiently dissolved in 500 ml of ethanol. Subsequently, 91.2 g of thiourea was added thereto and then, refluxed at 80° C. for 12 hours after dispersion. Then, an aqueous solution prepared by dissolving 60 g of NaOH in 200 ml of water was injected thereinto, an excessive amount of methylene chloride was added thereto, while further stirred for 5 hours, and a hydrochloric acid aqueous solution was added thereto after stirring and then, sequentially proceeds with extraction, appropriate or suitable, moisture removal, and solvent removal. After drying in a vacuum oven for 24 hours, surface-modifying materials shown in Table 2 was obtained.

### Synthesis Examples 2 to 9 and Comparative Synthesis Examples 1 to 3

Each surface-modifying material was obtained in substantially the same manner as in Preparation Example 1 except that each compound shown in Table 1 was utilized instead of the tetrahydrofurfuryl alcohol.

TABLE 1

| | Compounds |
|---|---|
| Synthesis Example 2 | Furfuryl alcohol |
| Synthesis Example 3 | Tetrahydro-2-thiophenemethanol |
| Synthesis Example 4 | 2-Thiophenemethanol |
| Synthesis Example 5 | 5-Isoxazolemethanol |
| Synthesis Example 6 | 5-Isothiazolemethanol |
| Synthesis Example 7 | 2-Dibenzofuranmethanol |
| Synthesis Example 8 | 2-Dibenzothiophenemethanol |
| Synthesis Example 9 | 3-Benzothiophenemethanol |
| Comparative Synthesis | Phenol |
| Example 1 | |
| Comparative Synthesis | 3-phenoxybenzyl alcohol |
| Example 2 | |
| Comparative Synthesis | Thiophenol |
| Example 3 | |

### Synthesis Example 10

279 g of the compound represented by Chemical Formula A synthesized in Preparation Example 1 and 180.62 g of allyl bromide (TCI) were put in two-necked round bottom flask and sufficiently dissolved in 500 mL of DMF (dimethyl formamide). Subsequently, 49.3 g of 60% NaOH was added thereto at 0° C. and then, stirred for 1 hour, and 500 ml of water was added thereto and after completing a reaction, the mixture was moved to a separation funnel. Then, 1000 mL of ethyl acetate was added thereto, and the solution was washed three times with 100 ml of a saturated sodium bicarbonate solution. After separating an organic layer therefrom, MgSO₄ was injected thereinto and then, filtered, concentrated, and dried in a drying oven for 24 hours, obtaining an intermediate product.

The intermediate product was put in a flask and then, dissolved in 500 mL of methylene chloride, stirred at 50° C. for 10 hours after adding 164 g of m-CPBA (Sigma Aldrich Co., Ltd.) thereto, redispersed in 300 ml of water after removing the solvent, and stirred at 60° C. for 6 hours after adding sulfuric acid thereto. The mixture obtained by separating moisture through a filter was column-purified (a mixed solvent of 3% ethanol and methylene chloride), and after removing the solvent, a diol compound was obtained.

A portion of the obtained product was diluted in a THF/deionized water (DIW) (w/w=5/5) solvent, and 2.2 equivalent of NaOH was added to the dispersion solution under an ice bath and then, stirred for 10 minutes. After adding a solution of 2.2 equivalent of p-toluenesulfonic chloride (30% in THF) dropwise thereto, stirring the mixture at room temperature for 12 hours, dissolving it in 300 mL of methylene chloride, and adding a diluted hydrochloric acid aqueous solution thereto, extraction and neutralization were three times performed. Subsequently, after removing moisture and the solvent therefrom, vacuum-drying was performed for 24 hours. The obtained product was put in a flask and dissolved in 300 mL of acetone, and 2.2 equivalent of potassium thioacetate (TCI) was added thereto and then, stirred at 60° C. for 12 hours. 300 mL of methylene chloride was added thereto, and after three times performing extraction with 200 ml of water and removing moisture and the solvent, vacuum-drying was performed for 24 hours. A product obtained therefrom was dissolved in 300 mL of ethanol, and 2.5 equivalent of hydrochloric acid was added thereto and then, stirred at 100° C. for 12 hours. An excessive amount of methylene chloride was added and the solution was washed with water five times, then neutralized, and the product was vacuum-dried for 24 hours after removing the solvent, obtaining each corresponding surface-modifying material.

### Comparative Synthesis Example 4

278 g of the compound represented by Chemical Formula A synthesized in Preparation Example 1, 96.6 g of thioglycolic acid (Sigma Aldrich Co., Ltd.), 20 g of p-toluenesulfonic acid monohydrate (Sigma Aldrich Co., Ltd.), and 500 mL of cyclohexane were heated to reflux the cyclohexane under a nitrogen atmosphere, and a dean stark device was utilized to remove water produced therefrom. If (e.g., when) the water was not produced any more, the reactant was cooled to room temperature then diluted with ethyl acetate and washed with distilled water. Subsequently, an organic layer was separated from moisture, neutralized by utilizing a NaOH dilution, several times washed with distilled water, treated with MgSO₄ to dry moisture, and concentrated under a reduced pressure, finally obtaining each corresponding surface-modifying material.

### Comparative Synthesis Example 5

A corresponding surface-modifying material was obtained in substantially the same manner as in Comparative Synthesis Example 4 except that 116 g of mercaptopropionic acid (Sigma Aldrich Co., Ltd.) was utilized instead of 96.6 g of the thioglycolic acid (Sigma Aldrich Co., Ltd.).

### Preparation of Surface-modified Quantum Dots

### Preparation Examples 1 to 10 and Comparative Preparation Examples 1 to 5

After putting a magnetic bar in a 3-necked round bottom flask, a green quantum dot dispersion solution (26 wt % of quantum dot solid; InP/ZnSe/ZnS, Hansol Chemical) was put therein. Then, a surface-modifying material according to Table 2 was added thereto and then, stirred at 80° C. under a nitrogen atmosphere. If (e.g., when) a reaction was completed, the quantum dot reaction solution was cooled to room temperature (23° C.) and added to cyclohexane to catch precipitates. The precipitates were separated from the cyclohexane through centrifugation and sufficiently dried in a vacuum oven for one day, obtaining surface-modified green quantum dots.

TABLE 2

| | Surface-modifying material |
|---|---|
| Preparation Example 1 | 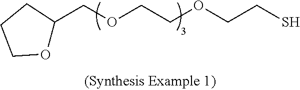 |
| Preparation Example 2 | 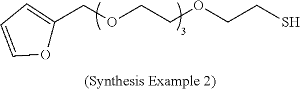 |
| Preparation Example 3 | 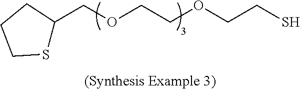 |
| Preparation Example 4 | 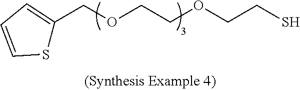 |
| Preparation Example 5 | 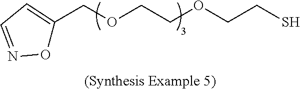 |
| Preparation Example 6 | 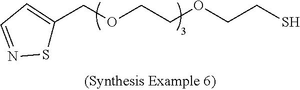 |
| Preparation Example 7 | 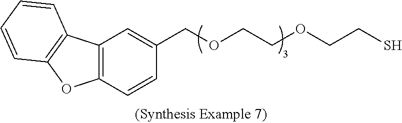 |
| Preparation Example 8 | 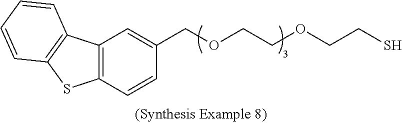 |
| Preparation Example 9 | 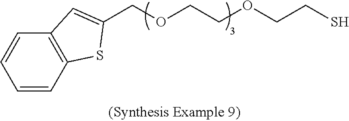 |
| Preparation Example 10 | 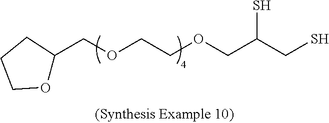 |
| Comparative Preparation Example 1 | 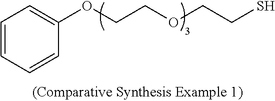 |
| Comparative Preparation Example 2 | 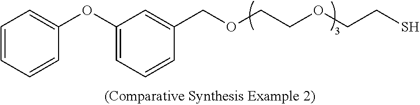 |
| Comparative Preparation Example 3 | 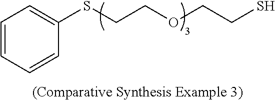 |
| Comparative Preparation Example 4 | 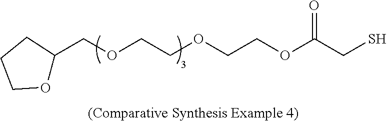 |
| Comparative Preparation Example 5 | 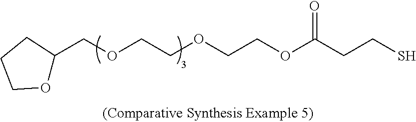 |

### Preparation of Curable Compositions

Based on each of the following components, curable compositions according to Examples 1 to 10 and Comparative Examples 1 to 5 were prepared.

### (A) Quantum Dots

(A-1) Surface-modified green quantum dots prepared from Preparation Example 1
(A-2) Surface-modified green quantum dots prepared from Preparation Example 2
(A-3) Surface-modified green quantum dots prepared from Preparation Example 3
(A-4) Surface-modified green quantum dots prepared from Preparation Example 4
(A-5) Surface-modified green quantum dots prepared from Preparation Example 5
(A-6) Surface-modified green quantum dots prepared from Preparation Example 6
(A-7) Surface-modified green quantum dots prepared from Preparation Example 7
(A-8) Surface-modified green quantum dots prepared from Preparation Example 8
(A-9) Surface-modified green quantum dots prepared from Preparation Example 9
(A-10) Surface-modified green quantum dots prepared from Preparation Example 10
(A-11) Surface-modified green quantum dots prepared from Comparative Preparation Example 1
(A-12) Surface-modified green quantum dots prepared from Comparative Preparation Example 2
(A-13) Surface-modified green quantum dots prepared from Comparative Preparation Example 3
(A-14) Surface-modified green quantum dots prepared from Comparative Preparation Example 4
(A-15) Surface-modified green quantum dots prepared from Comparative Preparation Example 5

### (B) Polymerizable Compound

Compound represented by Chemical Formula 6-2 (M200, Miwon Chemical Co., Ltd.)

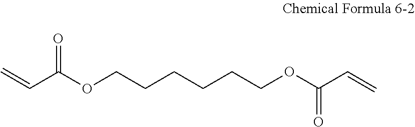 [SMILES: C=CC(=O)OCCCCCCOC(=O)C=C]

### (C) Photopolymerization Initiator

TPO-L (Polynetron Co.)

### (D) Light Diffusing Agent

Titanium dioxide dispersion (rutile type or kind TiO₂; D50 (180 nm), solid content (e.g., amount) 50 wt %, Iridos Co., Ltd.)

### (E) Polymerization Inhibitor

Methylhydroquinone (TOKYO CHEMICAL Co., Ltd.)

### Examples 1 to 10 and Comparative Examples 1 to 5

For example, the surface-modified green quantum dots and a polymerizable compound were mixed and stirred for 12 hours. Subsequently, a polymerization inhibitor was added thereto and then, stirred for 5 minutes. After adding a photopolymerization initiator thereto, a light diffusing agent was added thereto.

Illustrating Example 1 as an example, 41 g of the surface-modified green quantum dots and 41 g of the compound represented by Chemical Formula 6-2 as the polymerizable compound were mixed and stirred to prepare green quantum dot dispersion, 10.95 g of another curable monomer represented by Chemical Formula 6-2 and 0.05 g of the polymerization inhibitor were added thereto and then, stirred for 5 minutes, and subsequently, 3 g of the photopolymerization initiator and 4 g of the light diffusing agent were added thereto and then, stirred, preparing a curable composition (ink).

Each specific composition is shown in Table 3.

TABLE 3
(unit: wt %)

| | | Ex. | Ex. | Ex. | Ex. | Ex. | Ex. | Ex. | Ex. | Ex. | Ex. | Comp. | Comp. | Comp. | Comp. | Comp. |
|---|---|---|---|---|---|---|---|---|---|---|---|---|---|---|---|---|
| | | 1 | 2 | 3 | 4 | 5 | 6 | 7 | 8 | 9 | 10 | Ex. 1 | Ex. 2 | Ex. 3 | Ex. 4 | Ex. 5 |
| Quantum | (A-1) | 41 | — | — | — | — | — | — | — | — | — | — | — | — | — | — |
| dots | (A-2) | — | 41 | — | — | — | — | — | — | — | — | — | — | | — | — |
| | (A-3) | — | — | 41 | — | — | — | — | — | — | — | — | — | — | — | — |
| | (A-4) | — | — | — | 41 | — | — | — | — | — | — | — | — | — | — | — |
| | (A-5) | — | — | — | — | 41 | — | — | — | — | — | — | — | — | — | — |
| | (A-6) | — | — | — | — | — | 41 | — | — | — | — | — | — | — | — | — |
| | (A-7) | — | — | — | — | — | — | 41 | — | — | — | — | — | — | — | — |
| | (A-8) | — | — | — | — | — | — | — | 41 | — | — | — | — | — | — | — |
| | (A-9) | — | — | — | — | — | — | — | — | 41 | — | — | — | — | — | — |
| | (A-10) | — | — | — | — | — | — | — | — | — | 41 | — | — | — | — | — |
| | (A-11) | — | — | — | — | — | — | — | — | — | — | 41 | — | — | — | — |
| | (A-12) | — | — | — | — | — | — | — | — | — | — | — | 41 | — | — | — |
| | (A-13) | — | — | — | — | — | — | — | — | — | — | — | — | 41 | — | — |
| | (A-14) | — | — | — | — | — | — | — | — | — | — | — | — | — | 41 | — |
| | (A-15) | — | — | — | — | — | — | — | — | — | — | — | — | — | — | 41 |

| Polymerizable | 41 g |
|---|---|
| compound (for | |
| dispersion) | |
| Polymerizable | 10.95 g |
| compound | |
| Polymerization | 0.5 g |
| inhibitor | |
| Photopolymerization | 3 g |
| initiator | |
| Light diffusing | 4 g |
| agent | |

### Evaluation: Light Efficiency Evaluation of Curable Compositions

Each of the curable compositions according to Examples 1 to 10 and Comparative Examples 1 to 5 was evaluated with respect to light efficiency, and the results are shown in Table 4.

### Evaluation Method of Light Efficiency

1 The prepared curable composition was manufactured into a 2 centimeter (cm)×2 cm single film specimen and then, measured with respect to light efficiency over time under a light source condition of blue 20,000 nit (i.e., candela per square meter) by utilizing a blue LED planar light source.

The single film specimen was measured with respect to light efficiency and luminance over time by utilizing an integrating sphere equipment (QE-2100, Otsuka Electronics Co., Ltd.) and an in-line luminance meter (M7000, McScience Inc.).

Based on 100% of an initial measurement, T90 (time taken until 100% of the initial light efficiency measurement drops to 90%) was compared and evaluated.

TABLE 4

| | Initial light | T90 |
|---|---|---|
| | efficiency | (hr) |
| Example 1 | 33.3% | 910 |
| Example 2 | 32.6% | 860 |
| Example 3 | 33.0% | 876 |
| Example 4 | 32.1% | 902 |
| Example 5 | 32.5% | 842 |
| Example 6 | 33.0% | 884 |
| Example 7 | 32.4% | 820 |
| Example 8 | 32.4% | 812 |
| Example 8 | 33.1% | 830 |
| Example 10 | 33.8% | 980 |
| Comparative | 30.8% | 492 |
| Example 1 | | |
| Comparative | 30.1% | 360 |
| Example 2 | | |
| Comparative | 30.6% | 204 |
| Example 3 | | |
| Comparative | 27.5% | 400 |
| Example 4 | | |
| Comparative | 28.2% | 424 |
| Example 5 | | |

Referring to Table 3, the curable compositions of Examples 1 to 10 exhibit excellent or suitable light resistance reliability, compared with the curable compositions of Comparative Examples 1 to 5. In particular, the curable compositions of Comparative Examples 4 and 5 include surface-modified quantum dots surface-modified a surface-modifying material including an ester linking group and thus exhibit a large decrease in light efficiency due to a decrease in heat resistance, which confirms significant deterioration of light resistance reliability.

While this present disclosure has been described in connection with what is presently considered to be practical example embodiments, it is to be understood that the present disclosure is not limited to the disclosed embodiments, but, on the contrary, is intended to cover one or more suitable modifications and equivalent arrangements included within the spirit and scope of the appended claims and equivalents thereof. Therefore, the aforementioned embodiments should be understood to be example but not limiting the present disclosure in any way.

What is claimed is:

1. A curable composition, comprising
(A) quantum dots comprising at least one functional group selected from among functional groups represented by Chemical Formulas 1, 2-1, 2-2, and 2-3; and
(B) a polymerizable compound: 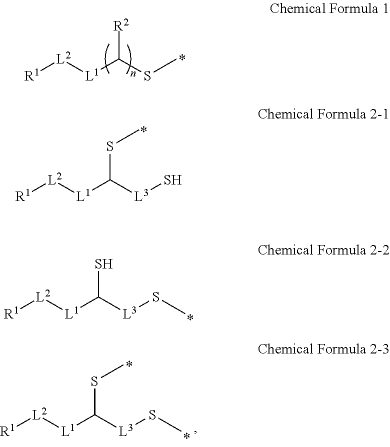
wherein, in Chemical Formulas 1, 2-1, 2-2, and 2-3,
L¹ is a single bond, a substituted or unsubstituted C1 to C20 alkylene group, an ether group (*—O—*), *—(X-L^{a})-* (wherein X is an oxygen atom or a sulfur atom, and L^{a} is a substituted or unsubstituted C1 to C10 alkylene group) or a combination thereof,
L² and L³ are each independently a single bond or a substituted or unsubstituted C1 to C20 alkylene group,
R¹ is a substituted or unsubstituted heterocyclic group,
R² is a hydrogen atom or a substituted or unsubstituted C1 to C20 alkyl group,
n is an integer of 0 or 1, and
“*” is a linking point with a different atom, a same chemical formula, or a different chemical formula.

2. The curable composition as claimed in claim 1, wherein
the substituted or unsubstituted heterocyclic group comprises a nitrogen atom, an oxygen atom, a sulfur atom, or a combination thereof.

3. The curable composition as claimed in claim 2, wherein
the unsubstituted heterocyclic group is represented by any one of Chemical Formulas H-1 to H-12:

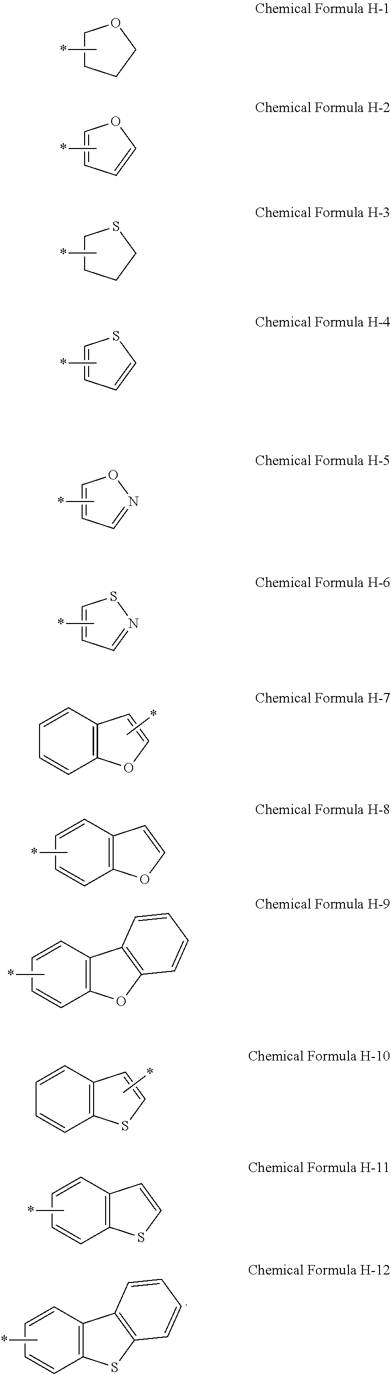

4. The curable composition as claimed in claim 1, wherein
the functional group represented by Chemical Formula 1 is represented by any one of Chemical Formulas 1A to 1C. 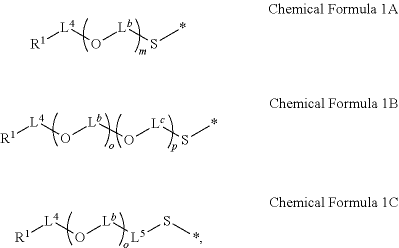
and
wherein, in Chemical Formulas 1A to 1C,
L⁴ is a single bond or a substituted or unsubstituted C1 to C20 alkylene group,
L⁵, L^{b}, and LG are each independently a substituted or unsubstituted C1 to C20 alkylene group,
R¹ is a substituted or unsubstituted heterocyclic group, and
m, o, and p are each independently an integer of 1 to 100.

5. The curable composition as claimed in claim 1, wherein
the functional groups represented by Chemical Formulas 2-1 to 2-3 are each represented by any one of Chemical Formulas 2A to 2F: 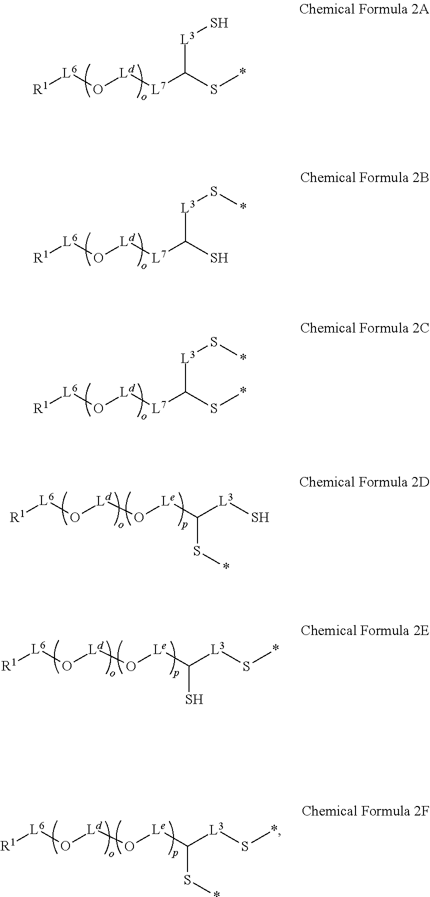
and
wherein, in Chemical Formulas 2A to 2F,
L³, L⁷, and L⁶ are each independently a single bond or a substituted or unsubstituted C1 to C20 alkylene group,
L^{d} and L^{e} are each independently a substituted or unsubstituted C1 to C20 alkylene group,
R¹ is a substituted or unsubstituted heterocyclic group, and
and p are each independently an integer of 1 to 100.

6. The curable composition as claimed in claim 1, wherein
the functional group represented by Chemical Formula 1 is represented by any one of Chemical Formulas 10 to 18: 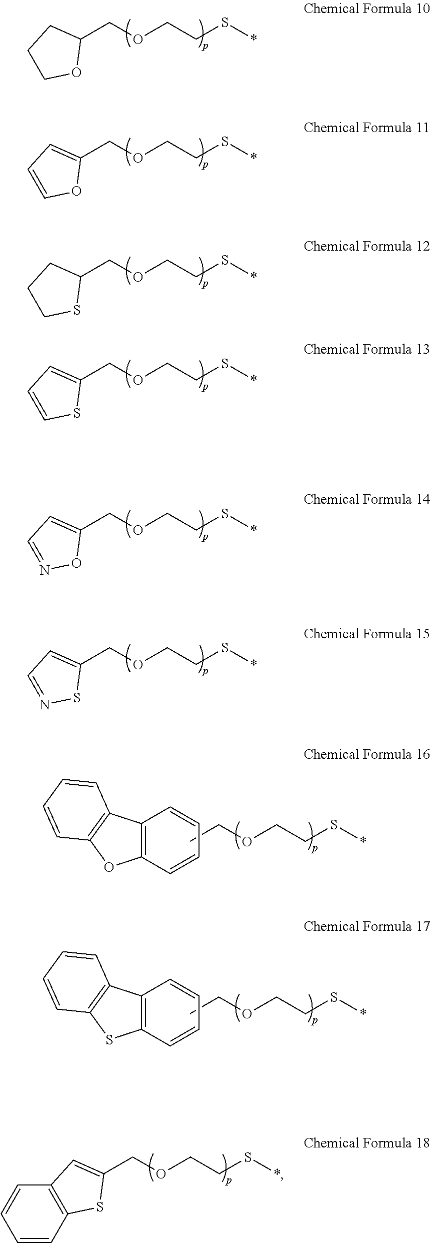
and
wherein, in Chemical Formulas 10 to 18,
p is an integer from 1 to 100.

7. The curable composition as claimed in claim 1, wherein
the functional group represented by Chemical Formulas 2-1 to 2-3 is represented by any one of Chemical Formulas 20 to 22: 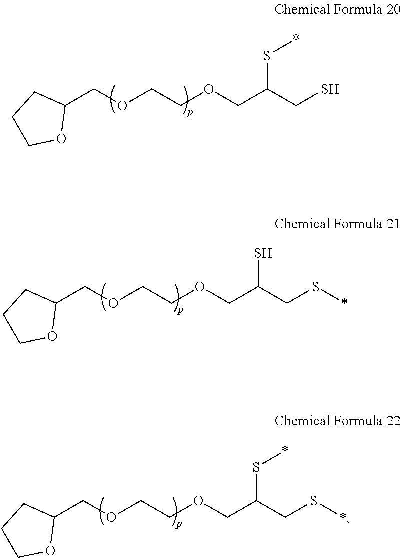
and
wherein, in Chemical Formulas 20 to 22,
p is an integer from 1 to 100.

8. A curable composition, comprising
(A) surface-modified quantum dots with a surface-modifying material; and
(B) a polymerizable compound
wherein the surface-modifying material comprises at least one selected from among compounds represented by Chemical Formulas 3 and 4: 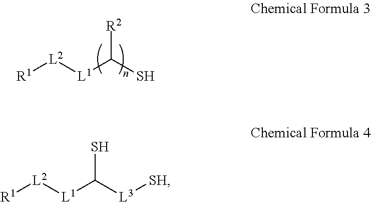
and
wherein, in Chemical Formulas 3 and 4,
L¹ is a single bond, a substituted or unsubstituted C1 to C20 alkylene group, an ether group (*—O—*), *—(X-L^{a})-* (wherein X is an oxygen atom or a sulfur atom, and L^{a} is a substituted or unsubstituted C1 to C10 alkylene group) or a combination thereof,
L² and L³ are each independently a single bond or a substituted or unsubstituted C1 to C20 alkylene group,
R¹ is a substituted or unsubstituted heterocyclic group,
R² is a hydrogen atom or a substituted or unsubstituted C1 to C20 alkyl group,
n is an integer of 0 or 1, and
“*” is a linking point with a different atom, a same chemical formula, or a different chemical formula.

9. The curable composition as claimed in claim 8, wherein
the substituted or unsubstituted heterocyclic group comprises a nitrogen atom, an oxygen atom, a sulfur atom, or a combination thereof.

10. The curable composition as claimed in claim 9, wherein
the unsubstituted heterocyclic group is represented by any one of Chemical Formulas H-1 to H-12:

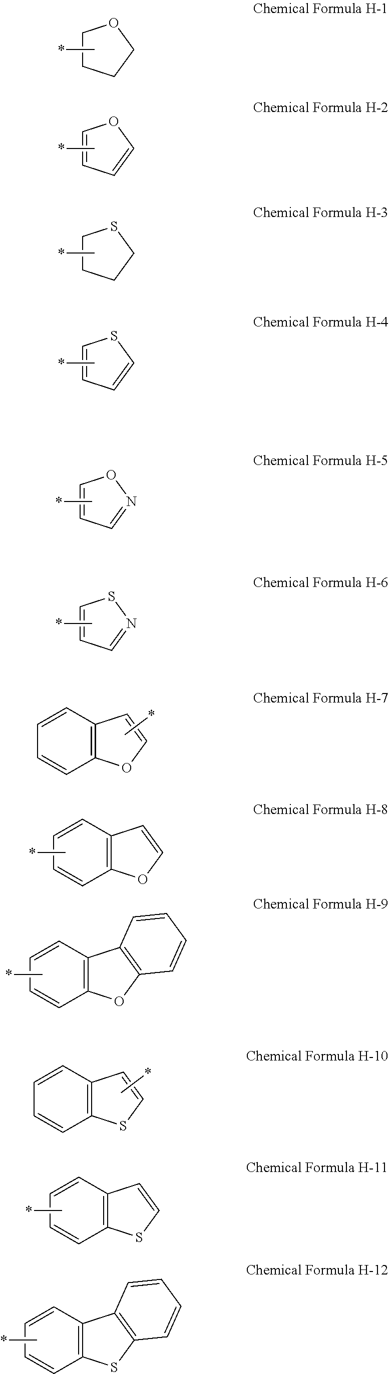

11. The curable composition as claimed in claim 8, wherein
the compound represented by Chemical Formula 3 is represented by any one of Chemical Formulas 3A to 3C. 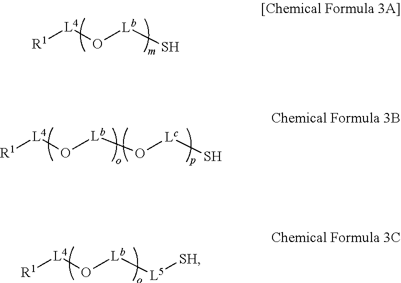
and
wherein, in Chemical Formulas 3A to 3C,
L⁴ is a single bond or a substituted or unsubstituted C1 to C20 alkylene group,
L⁵, L^{b}, and L^{c} are each independently a substituted or unsubstituted C1 to C20 alkylene group,
R¹ is a substituted or unsubstituted heterocyclic group, and
m, o, and p are each independently an integer of 1 to 100.

12. The curable composition as claimed in claim 8, wherein
the compound represented by Chemical Formula 4 is represented by any one of Chemical Formulas 4A or 4B: 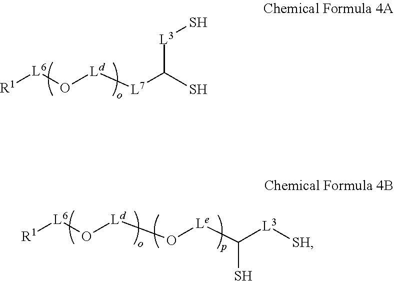
and
wherein, in Chemical Formulas 4A to 4B,
L³, L⁷, and L⁶ are each independently a single bond or a substituted or unsubstituted C1 to C20 alkylene group,
L^{d} and L^{e} are each independently a substituted or unsubstituted C1 to C20 alkylene group,
R¹ is a substituted or unsubstituted heterocyclic group, and
o and p are each independently an integer of 1 to 100.

13. The curable composition as claimed in claim 8, wherein
the surface-modifying material is represented by any one of Chemical Formulas 30 to 38: 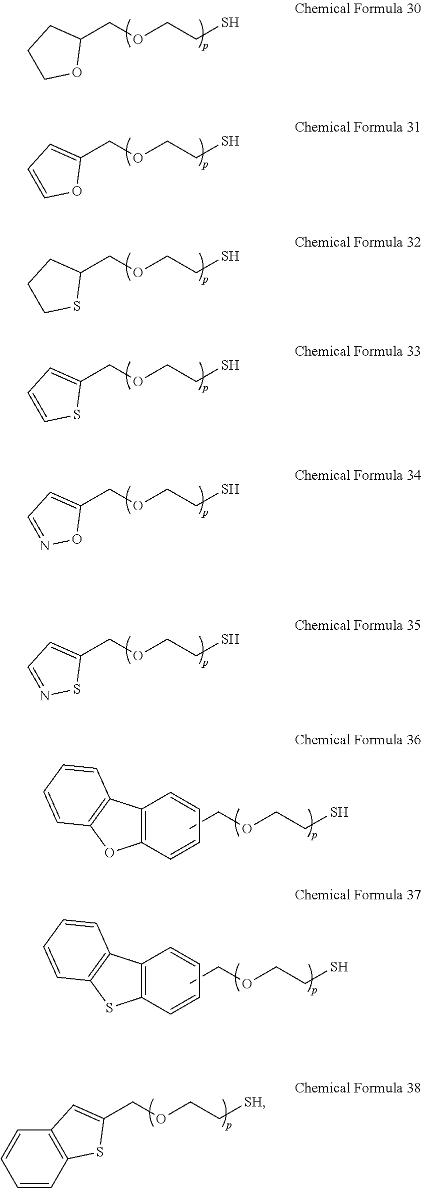
and
wherein, in Chemical Formulas 30 to 38,
p is an integer from 1 to 100.

14. The curable composition as claimed in claim 8, wherein
the surface-modifying material is represented by Chemical Formula 40. 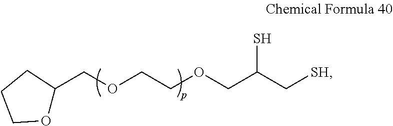
and
wherein, in Chemical Formula 40,
p is an integer from 1 to 100.

15. The curable composition as claimed in claim 1, wherein
the curable composition is a solvent-free curable composition.

16. The solvent-free curable composition as claimed in claim 15, wherein
the solvent-free curable composition comprises,
about 5 wt % to about 60 wt % of the quantum dots, and
about 40 wt % to about 95 wt % of the polymerizable compound,
based on a total amount of the solvent-free curable composition

17. The curable composition as claimed in claim 1, wherein
the curable composition further comprises a polymerization initiator, a light diffusing agent, a polymerization inhibitor, or a combination thereof.

18. The curable composition as claimed in claim 17, wherein
the light diffusing agent comprises barium sulfate, calcium carbonate, titanium dioxide, zirconia, or a combination thereof.

19. The curable composition as claimed in claim 1, wherein
the curable composition further comprises a solvent.

20. The curable composition as claimed in claim 19, wherein
the curable composition comprises,
about 1 wt % to about 40 wt % of the quantum dots,
about 1 wt % to about 20 wt % of the polymerizable compound, and
and about 40 wt % to about 80 wt % of the solvent,
based on a total weight of the curable composition.

21. The curable composition as claimed in claim 1, wherein
the curable composition further comprises malonic acid; 3-amino-1,2-propanediol; a silane-based coupling agent; a leveling agent; a fluorine-based surfactant; or a combination thereof.

22. A cured layer produced utilizing the curable composition as claimed in claim 1.

23. A display device comprising the cured layer as claimed in claim 22.
